(19) United States
(12) Patent Application Publication
(10) Pub. No.: US 2018/0003806 A1
(43) Pub. Date: Jan. 4, 2018

(54) OPTICAL APPARATUS, SYSTEM, AND TRANSPORT APPARATUS

(71) Applicant: CANON KABUSHIKI KAISHA, Tokyo (JP)

(72) Inventor: Fumihiro Inui, Yokohama-shi (JP)

(21) Appl. No.: 15/635,066

(22) Filed: Jun. 27, 2017

(30) Foreign Application Priority Data
Jun. 30, 2016 (JP) 2016-130905

(51) Int. Cl. G01S 7/486; G01S 17/10; H01L 27/146; H01L 31/167

(52) U.S. Cl. CPC G01S 7/4861; H01L 31/167; G01S 17/10; H01L 27/14636; H01L 27/14643

(57) ABSTRACT

A photoelectric conversion device generates a signal correlated with a difference between a first potential at a first detection node and a second potential at a second detection node, the first potential based on electrons that are generated by a first photoelectric conversion portion and collected to a first collection node in a first period, and on holes that are generated by a second photoelectric conversion portion and collected to a second collection node in a second period different from the first period, the second potential based on holes that are generated by the second photoelectric conversion portion and collected to a fourth collection node in the first period, and on electrons that are generated by the first photoelectric conversion portion and collected to a third collection node in the second period.

### BACKGROUND OF THE INVENTION

### Field of the Invention

The present technology relates to an optical apparatus including photoelectric conversion portions.

### Description of the Related Art

There is a ranging apparatus (distance sensor) using a time of flight (TOF) method. In the TOF method, a target of distance measurement is irradiated with light emitted by a light source, and the light reflected by the target is received. On the basis of the relationship between the speed of light and the time period from the irradiation to the light reception, the distance to the target is calculated. Here, the light that has been emitted by the light source for ranging and reflected by the target is referred to as signal light. The received light includes, in addition to the signal light, light (ambient light) derived from a light source different from the light source for ranging, such as natural light or artificial light. To enhance the ranging accuracy, it is effective to separate the ambient light and the signal light from each other.

Japanese Patent Laid-Open No. 2005-303268 discloses a technique of removing a component corresponding to ambient light by an apparatus that performs ranging by using a light detecting element. According to the second embodiment of this publication, the light detecting element includes a first photosensitive portion which has a suitable structure for picking out holes and a second photosensitive portion which has a suitable structure for picking out electrons. The holes generated at the first photosensitive portion are held by a hole holding portion through a gate portion, and the electrons generated at the second photosensitive portion are held by an electron holding portion through the gate portion. The holes held by the hole holding portion and the electrons held by the electron holding portion are recombined by a recombination portion, and the carriers remaining after the recombination are picked out as object carriers through an output portion.

### SUMMARY OF THE INVENTION

According to a first aspect of the present disclosure, there is provided an apparatus including a photoelectric conversion device. The photoelectric conversion device includes a first photoelectric conversion portion configured to generate electrons, a second photoelectric conversion portion configured to generate holes, a first detection node connected to a first collection node and a second collection node, the first collection node configured to collect the electrons generated by the first photoelectric conversion portion, the second collection node configured to collect the holes generated by the second photoelectric conversion portion, and a second detection node connected to a third collection node and a fourth collection node, the third collection node configured to collect the electrons generated by the first photoelectric conversion portion, the fourth collection node configured to collect the holes generated by the second photoelectric conversion portion. The apparatus generates a signal correlated with a difference between a first potential at the first detection node and a second potential at the second detection node. The first potential is based on electrons that are generated by the first photoelectric conversion portion and collected to the first collection node in a first period, and based on holes that are generated by the second photoelectric conversion portion and collected to the second collection node in a second period different from the first period. The second potential is based on holes that are generated by the second photoelectric conversion portion and collected to the fourth collection node in the first period, and based on electrons that are generated by the first photoelectric conversion portion and collected to the third collection node in the second period.

According to a second aspect of the present disclosure, there is provided an apparatus including a photoelectric conversion device. The photoelectric conversion device includes a first photoelectric conversion portion configured to generate electrons, a second photoelectric conversion portion configured to generate holes, a first detection node connected to a first collection node and a second collection node, the first collection node configured to collect the electrons generated by the first photoelectric conversion portion, the second collection node configured to collect the holes generated by the second photoelectric conversion portion, a second detection node connected to a third collection node and a fourth collection node, the third collection node configured to collect the electrons generated by the first photoelectric conversion portion, the fourth collection node configured to collect the holes generated by the second photoelectric conversion portion, and a switch configured to connect the first detection node and the second detection node to each other.

According to a third aspect of the present disclosure, there is provided an apparatus including a photoelectric conversion device. The photoelectric conversion device includes a first photoelectric conversion portion configured to generate electrons, a second photoelectric conversion portion configured to generate holes, a first detection node connected to a first collection node and a second collection node, the first collection node configured to collect the electrons generated by the first photoelectric conversion portion, the second collection node configured to collect the holes generated by the second photoelectric conversion portion, a second detection node connected to a third collection node and a fourth collection node, the third collection node configured to collect the electrons generated by the first photoelectric conversion portion, the fourth collection node configured to collect the holes generated by the second photoelectric conversion portion, a first signal generation portion connected to the first detection node, and a second signal generation portion connected to the second detection node.

Further features of the present invention will become apparent from the following description of example embodiments with reference to the attached drawings.

### BRIEF DESCRIPTION OF THE DRAWINGS

FIGS. 1A and 1B are schematic diagrams for describing a photoelectric conversion device, a ranging apparatus, and an information processing system.

FIG. 2 is a schematic diagram for describing an operation of the photoelectric conversion device.

FIG. 3 is a schematic diagram for describing a circuit of the photoelectric conversion device.

FIGS. 4A to 4D are schematic diagrams for describing an operation of the photoelectric conversion device.

FIGS. 5A to 5D are schematic diagrams for describing a structure of the photoelectric conversion device.

FIGS. 6A to 6D are schematic diagrams for describing structures of the photoelectric conversion device.

FIGS. 7A and 7B are schematic diagrams for describing circuits of the photoelectric conversion device.

FIGS. 8A to 8D are schematic diagrams for describing an operation of the photoelectric conversion device.

### DESCRIPTION OF THE EMBODIMENTS

In Japanese Patent Laid-Open No. 2005-303268, consideration for increasing the accuracy of signals is not sufficiently given. For example, if there is a difference in characteristics between the photosensitive portion that picks out holes and the photosensitive portion that picks out electrons, an error occurs in information that is obtained. Also, an error occurs in signals if there is a difference in characteristics between the gate portion that transfers holes and the gate portion that transfers electrons.

An embodiment is directed to increasing the accuracy of information that is based on electrons and holes generated by respective photoelectric conversion portions.

### Embodiment

Hereinafter, an embodiment of the present technology will be described with reference to the attached drawings. In the following description and the attached drawings, the same elements are denoted by the same reference numerals throughout a plurality of figures. Thus, the same elements will be described with reference to the plurality of figures, and the description of the elements denoted by the same reference numerals is appropriately omitted.

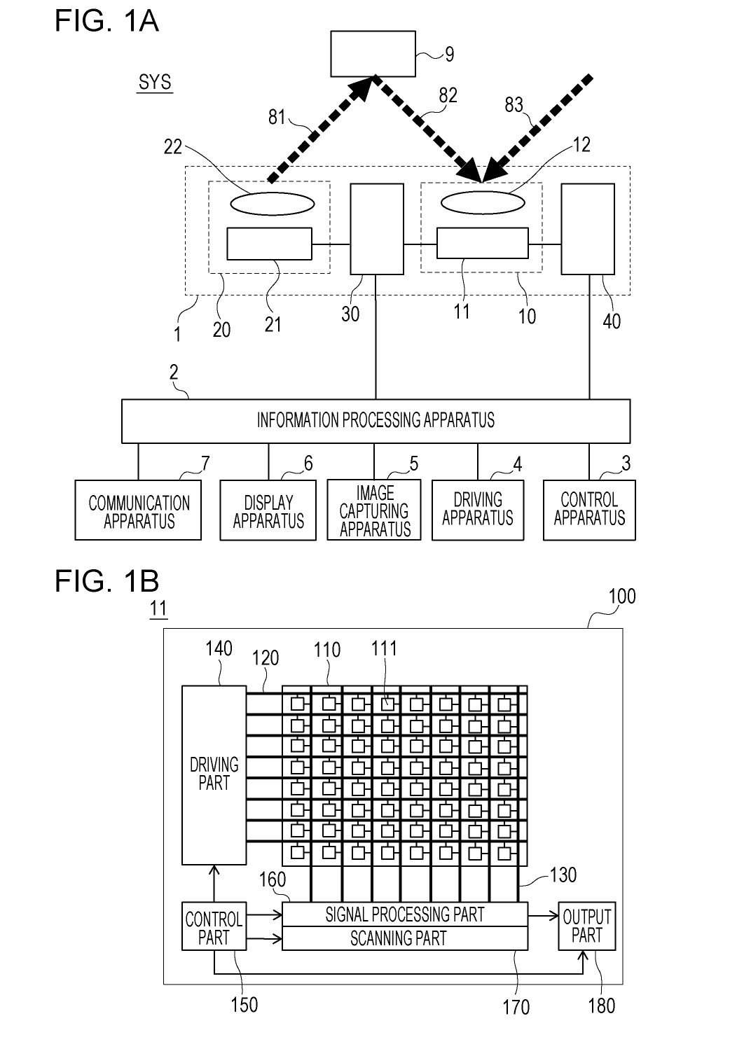

With reference to FIG. 1A, a description will be given of a photoelectric conversion device 11 and an information processing system SYS including the photoelectric conversion device 11. The information processing system SYS includes a ranging apparatus 1 and may further include at least any one of an information processing apparatus 2, a control apparatus 3, a driving apparatus 4, an image capturing apparatus 5, a display apparatus 6, and a communication apparatus 7. In the information processing system SYS, the photoelectric conversion device 11 is included in the ranging apparatus 1. The image capturing apparatus 5 may include a photoelectric conversion device different from the photoelectric conversion device 11 of the ranging apparatus 1. Alternatively, the photoelectric conversion device 11 may function as a photoelectric conversion device of the ranging apparatus 1 and a photoelectric conversion device of the image capturing apparatus 5. Application examples of the information processing system SYS will be described below.

The ranging apparatus 1 is an optical apparatus including a light receiving unit 10 and a light emitting unit 20. The light receiving unit 10 includes the photoelectric conversion device 11 and an optical system 12 that controls incident light on the photoelectric conversion device 11. The light emitting unit 20 includes a light emitting device 21 serving as a light source and an optical system 22 that controls outgoing light from the light emitting device 21. As the light emitting device 21, a light emitting diode may be used because it is capable of repeatedly blinking at high speed. The wavelength of light emitted by the light emitting device 21 may be infrared for the purpose of reducing color mixture with ambient light mainly including visible light. Infrared is hard to be visually identified by a human and thus can be comfortably used. However, the embodiment is not limited to infrared light. The optical systems 12 and 22 each include a lens, a diaphragm, a mechanical shutter, a scattering plate, an optical low-pass filter, a wavelength selection filter, and so forth. For example, the optical system 12 may include a filter having a higher transmittance for infrared light than that for visible light. The ranging apparatus 1 illustrated in FIG. 1A includes the optical systems 12 and 22, but at least any one of these optical systems may be omitted. In the case of using laser light as a light source, the optical system 22 may include a scanning optical system for scanning the light emitted by the light emitting unit 20 toward a predetermined region.

The ranging apparatus 1 may include a control unit 30 that is connected to at least one of the light receiving unit 10 and the light emitting unit 20. The control unit 30 drives and/or controls at least one of the light receiving unit 10 and the light emitting unit 20. The control unit 30 according to the embodiment that is connected to both the light receiving unit 10 and the light emitting unit 20 is capable of driving and/or controlling both the light receiving unit 10 and the light emitting unit 20, and, in one embodiment, is capable of driving and/or controlling both of them in synchronization. The control unit 30 is also capable of operating in response to a signal received from the information processing apparatus 2. The ranging apparatus 1 may include a processing unit 40 that is connected to the light receiving unit 10. The processing unit 40 processes signals output from the light receiving unit 10. The signals processed by the processing unit 40 may be transmitted to the information processing apparatus 2. At least one of the control unit 30 and the processing unit 40 is capable of operating in response to a signal received from the information processing apparatus 2.

Light 81 emitted by the light emitting unit 20 is applied to a target 9, is reflected by the target 9, and is received as signal light 82 by the light receiving unit 10. A difference based on the distance from the ranging apparatus 1 to the target 9 and the speed of light (3×10⁸ m/s) is generated between a light emission time at the light emitting unit 20 and a light reception time at the light receiving unit 10. With the physical amount corresponding to the time difference being detected, the distance from the ranging apparatus 1 to the target 9 or information based on the distance from the ranging apparatus 1 to the target 9 can be obtained as, for example, image data. The ranging apparatus 1 is a ranging apparatus using a time of flight (TOF) method. The degree of the above-described time difference can be detected by measuring a phase difference of light that periodically changes or the number of light pulses. A large interval between the light emitting unit 20 and the light receiving unit 10 could make a ranging algorithm complicated, and thus the interval between the light emitting unit 20 and the light receiving unit 10 may be set to be shorter than the interval corresponding to desired ranging accuracy. For example, the interval between the light emitting unit 20 and the light receiving unit 10 is set to 1 m or less.

Not only the signal light 82 but also ambient light 83 derived from a light source other than the light emitted by the light emitting device 21 as a light source enter the light receiving unit 10. The light source of the ambient light 83 is natural light or artificial light. The ambient light 83 is a noise component when ranging is performed. Thus, if the ratio of the ambient light 83 to received light is high, the dynamic range of a signal based on the signal light 82 decreases or the S/N ratio decreases, and it is difficult to accurately obtain distance information from the signal light 82. The photoelectric conversion device 11 according to the embodiment is capable of removing at least part of a component resulted from the ambient light 83 from a signal generated based on the light received by the photoelectric conversion device 11. Accordingly, the ranging accuracy can be enhanced. Although the details will be described below, in the embodiment, at least part of a component resulted from the ambient light 83 is removed by using a signal corresponding to a difference in the amount of signal charge generated by a plurality of photoelectric conversion portions. Furthermore, with use of electrons and holes as signal charge, the difference in the amount of charge can be accurately detected by using a simple structure. Accordingly, the ranging accuracy can be enhanced.

An overview of the photoelectric conversion device 11 according to the embodiment will be described with reference to FIG. 1B. The photoelectric conversion device 11 includes a cell array 110 on a semiconductor substrate 100. The cell array 110 includes a plurality of photoelectric conversion cells 111, which are arranged in a matrix formed of a plurality of rows and a plurality of columns. The photoelectric conversion device 11 may also include, on the semiconductor substrate 100, row wiring lines 120, column wiring lines 130, a driving part 140, a control part 150, a signal processing part 160, a scanning part 170, and an output part 180. The plurality of photoelectric conversion cells 111 in the cell array 110 are connected to the driving part 140 through the row wiring lines 120 located on the semiconductor substrate 100 in units of rows. The driving part 140 selectively inputs drive signals, such as transfer signals or reset signals, to the plurality of photoelectric conversion cells 111 sequentially or simultaneously. The plurality of photoelectric conversion cells 111 in the cell array 110 are connected to the signal processing part 160 through the column wiring lines 130 located on the semiconductor substrate 100 in units of columns. The signal processing part 160 processes the signals output from the photoelectric conversion cells 111 through the column wiring lines 130. The signal processing part 160 may include, for each column of the cell array 110, a CDS circuit, an amplification circuit, and an AD conversion circuit. The scanning part 170 causes the signals that have been output from the cell array 110 to the signal processing part 160 through the individual column wiring lines 130 and processed by the signal processing part 160 and that correspond to the individual columns to be sequentially output from the signal processing part 160 to the output part 180. The output part 180 outputs the signals received from the signal processing part 160 to the outside of the photoelectric conversion device 11 and may include an amplification circuit, a protection circuit, and an electrode for establishing a connection with an external circuit. The control part 150 generates control signals and controls the operation timings of the driving part 140, the signal processing part 160, the scanning part 170, and the output part 180 by using the control signals.

An on-chip lens array (microlens array) and a wavelength filter may be provided on an incidence surface side of the semiconductor substrate 100. The incidence surface side may be identical to the side on which the row wiring lines 120 and the column wiring lines 130 are provided on the semiconductor substrate 100 (front surface side). With this arrangement, a front-surface-irradiation photoelectric conversion device can be obtained. If the incidence surface side is opposite to the side on which the row wiring lines 120 and the column wiring lines 130 are provided on the semiconductor substrate 100 (rear surface side), a rear-surface-irradiation photoelectric conversion device can be obtained.

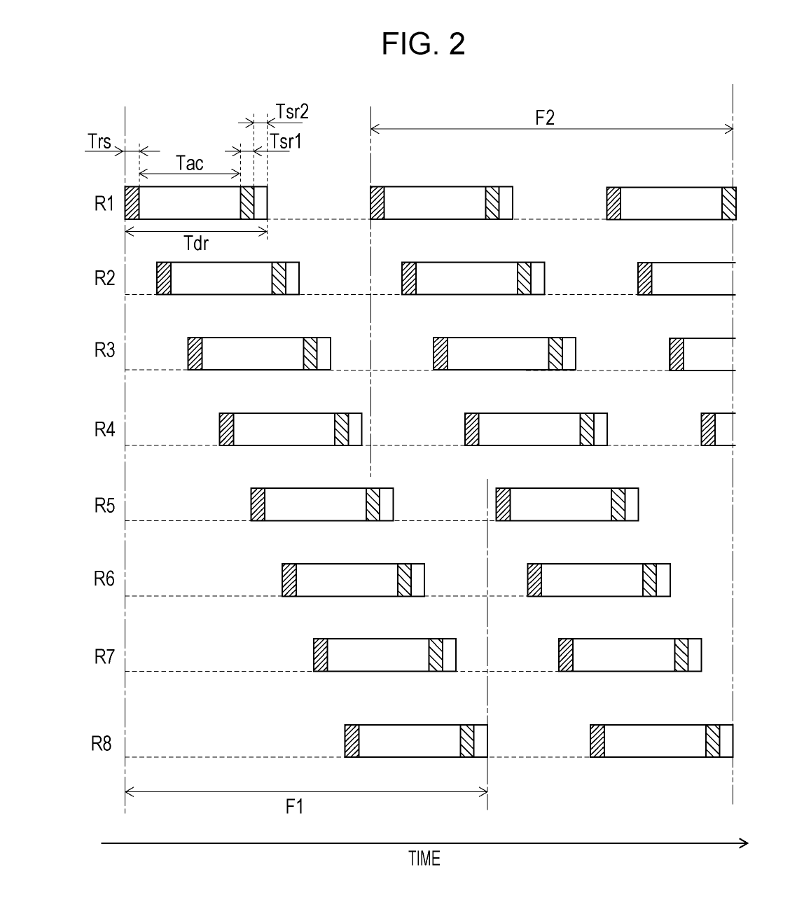

FIG. 2 illustrates an operation in eight rows in a case where the cell array 110 includes eight rows of the photoelectric conversion cells 111. In the example illustrated in FIG. 2, progressive scanning is performed on a first row R1 to an eighth row R8. Alternatively, interlace scanning may be performed.

A drive period Tdr for one photoelectric conversion cell 111 includes a reset period Trs in which a reset operation is performed, and an accumulation period Tac in which an accumulation operation for accumulating charge based on the signal light 82 is performed. The drive period Tdr also includes a read period Tsr1 in which a read operation for reading a first signal based on accumulated charge is performed, and a read period Tsr2 in which a read operation for reading a second signal based on accumulated charge is performed. The read period Tsr1 and the read period Tsr2 may also be referred to as periods in which output from the photoelectric conversion cell to the column wiring line is performed. The read period Tsr1 and the read period Tsr2 may be identical to each other depending on the circuit configuration. The drive period Tdr may further include a period in which another desired operation is performed. In this example, the plurality of photoelectric conversion cells 111 belonging to the same row are simultaneously driven within a single drive period Tdr. The signals output from the plurality of photoelectric conversion cells 111 belonging to the same row of the cell array 110 are processed by the signal processing part 160 and are output to the output part 180, as described above with reference to FIG. 1B. In another example, a first signal based on accumulated charge and a second signal based on accumulated charge are processed by the signal processing part 160, and a computation result such as the sum of the two signals or the difference between the two signals is output to the output part 180.

A frame period is a period in which reset operations, accumulation operations, and read operations are performed in all the rows of the photoelectric conversion cells 111 constituting the cell array 110. For example, the starting point of a first frame period F1 is the time point at which the reset operation in the first row R1 is started, and the end point of the first frame period F1 is the time point at which the read operation in the photoelectric conversion cells 111 in the eighth row R8 is ended. The starting point of a second frame period F2 is the time point at which the reset operation in the first row R1 is started for the first time after the read operation in the first row R1 is ended in the first frame period F1. The end point of the second frame period F2 is the time point at which the read operation in the eighth row R8 is ended for the first time after the read operation in the eighth row R8 is ended in the first frame period F1.

As illustrated in FIG. 2, the accumulation operations in a plurality of rows (in this example, three to four rows) are performed in parallel, and thus the accumulation period can be extended and the output of signals obtained in the accumulation period can be increased. Even when the accumulation operations in a plurality of rows are performed in parallel, signals in the plurality of rows can be separated from one another by making the read operation timing different among the rows.

Furthermore, as a result of performing a series of operations so that part of the first frame period F1 overlaps part of the second frame period F2 as illustrated in FIG. 2, the frame rate can be increased or one frame period can be extended. That is, in FIG. 2, at the time when the read operations in the first to fourth rows are ended in the first frame period F1, the reset operation and the accumulation operation in the first row are started.

The embodiment is not limited to this example. After all the reset operation, accumulation operation, and read operation in one row have been ended, the reset operation, accumulation operation, and read operation in the next row may be started. Alternatively, after the read operation in the last row (eighth row) has been ended, the reset operation in the first row may be started.

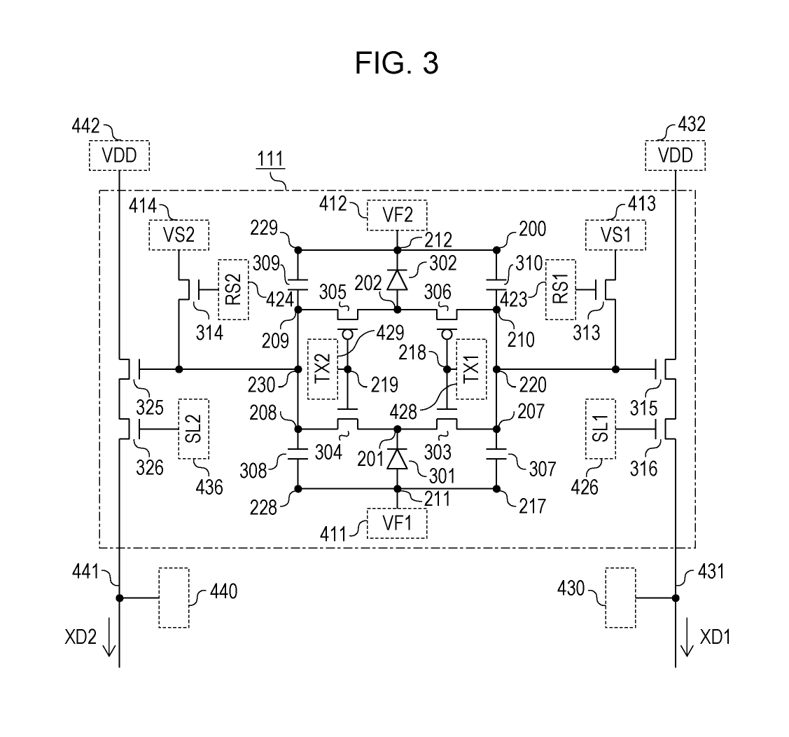

Next, a description will be given of an example structure of each photoelectric conversion cell 111. FIG. 3 illustrates an equivalent circuit of the photoelectric conversion cell 111. In FIG. 3, the elements included in the photoelectric conversion cell 111 as a repetition unit of the matrix are surrounded by a chained line. Note that, regarding the elements surrounded by a broken line, part of the elements may be located outside the cell array 110 (for example, the driving part 140).

The photoelectric conversion cell 111 includes a photoelectric conversion portion 301 and a photoelectric conversion portion 302. The photoelectric conversion portion 301 generates electrons as signal charge through photoelectric conversion, whereas the photoelectric conversion portion 302 generates holes as signal charge through photoelectric conversion. That is, the positive/negative sign of the signal charge generated by the photoelectric conversion portion 301 is opposite to that of the signal charge generated by the photoelectric conversion portion 302. However, the photoelectric conversion portion 301 generates holes as well as electrons and the photoelectric conversion portion 302 generates electrons as well as holes. Each of the photoelectric conversion portions 301 and 302 is a PN photodiode or PIN photodiode, and may be a buried photodiode in view of reducing dark current. Using buried photodiodes as the photoelectric conversion portions 301 and 302 is beneficial in terms of reducing dark current compared to the case of using photogates as the photoelectric conversion portions 301 and 302 and increasing the S/N ratio to clearly receive weak signal light. The photodiode serving as the photoelectric conversion portion 301 includes a cathode 201, which is an n-type semiconductor region where electrons are majority carriers, and an anode 211, which is a p-type semiconductor region where electrons are minority carriers. The photodiode serving as the photoelectric conversion portion 302 includes an anode 202, which is a p-type semiconductor region where holes are majority carriers, and a cathode 212, which is an n-type semiconductor region where holes are minority carriers.

The photoelectric conversion cell 111 includes a capacitor portion 307 capable of holding electrons as signal charge generated by the photoelectric conversion portion 301, and a capacitor portion 310 capable of holding holes as signal charge generated by the photoelectric conversion portion 302.

The capacitor portion 307 includes a reference node 217 and a collection node 207. The collection node 207 collects electrons as signal charge generated by the photoelectric conversion portion 301. The capacitor portion 307 is configured so that a potential difference corresponding to the amount of charge held by the capacitor portion 307 appears between the collection node 207 and the reference node 217. That is, the capacitor portion 307 functions as a charge-to-voltage conversion portion that converts the amount of charge to a voltage. The capacitor portion 310 includes a reference node 200 and a collection node 210. The collection node 210 collects holes as signal charge generated by the photoelectric conversion portion 302. The capacitor portion 310 is configured so that a potential difference corresponding to the amount of charge held by the capacitor portion 310 appears between the collection node 210 and the reference node 200. That is, the capacitor portion 310 functions as a charge-to-voltage conversion portion that converts the amount of charge to a voltage.

The capacitor portions 307 and 310 each have a p-n junction diode structure. The reference node 217 and the collection node 210 are p-type semiconductor regions, whereas the reference node 200 and the collection node 207 are n-type semiconductor regions. The collection nodes 207 and 210 that hold signal charge are floating nodes that are electrically floating. The semiconductor regions constituting the collection nodes 207 and 210 are impurity diffusion regions in a floating state, that is, floating diffusion. The collection node 207, which is an n-type semiconductor region, may collect electrons as signal charge and hold the electrons. The collection node 210, which is a p-type semiconductor region, may collect holes as signal charge and hold the holes. Although the details will be described below, the photoelectric conversion device 11 is capable of operating so that signal charge is selectively held by one of the collection nodes 207 and 210.

The photoelectric conversion cell 111 includes a transfer portion 303 in order to efficiently collect electrons, among the electrons and holes generated by the photoelectric conversion portion 301, to the collection node 207 of the capacitor portion 307. Also, the photoelectric conversion cell 111 includes a transfer portion 306 in order to efficiently collect holes, among the electrons and holes generated by the photoelectric conversion portion 302, to the collection node 210 of the capacitor portion 310. Thus, the collection nodes 207 and 210 can also be referred to as nodes to which signal charge is transferred from the photoelectric conversion portions 301 and 302, respectively. Since the collection nodes 207 and 210 are capable of holding the charge transferred from the photoelectric conversion portions 301 and 302, the collection nodes (capacitor portions) can also be referred to as charge holding portions.

The transfer portions 303 and 306 each have an MIS gate structure. Specifically, the transfer portions 303 and 306 have a multilayer structure including a semiconductor region (channel region), a gate insulating film, and a gate electrode. Thus, the transfer portions 303 and 306 can also be referred to as transfer gates. When the transfer portion 303 is in an ON state (conducting state), inversion forms an n-type channel in the semiconductor region. When the transfer portion 306 is in an ON state, inversion forms a p-type channel in the semiconductor region. In this way, the conductivity types of the transfer portions 303 and 306 are different from each other.

In this example, the gate electrode of the transfer portion 303 and the gate electrode of the transfer portion 306 are connected in common to a transfer node 218. The transfer node 218 is connected to a transfer signal output portion 428, and a transfer signal TX1 is input from the transfer signal output portion 428 to the transfer node 218. The transfer portions 303 and 306 have different conductivity types and are configured to operate complementarily. That is, the transfer portion 306 is in an OFF state (non-conducting state) in a period when the transfer portion 303 is in an ON state in response to the transfer signal TX1, and the transfer portion 306 is in an ON state in a period when the transfer portion 303 is in an OFF state in response to the transfer signal TX1.

A threshold may be set so that both the transfer portions 303 and 306 are brought into an OFF state when the transfer node 218 is at a predetermined potential. The predetermined potential may be a potential between the potential at which the transfer portion 303 is in an ON state and the transfer portion 306 is in an OFF state and the potential at which the transfer portion 303 is in an OFF state and the transfer portion 306 is in an ON state. Such a predetermined potential is determined in accordance with the potential in the semiconductor region in the MIS gate structure and a threshold of the MIS gate structure. A difference between a potential level High at which the transfer portion 303 is in an ON state and a potential level Mid at which the transfer portion 303 is in an OFF state is, for example, 1 to 5 V. A difference between a potential level Low at which the transfer portion 306 is in an ON state and the potential level Mid at which the transfer portion 303 is in an OFF state is, for example, 1 to 5 V. The potential level High may be set to a potential (positive potential) higher than a ground potential GND (0 V), and the potential level Low may be set to a potential (negative potential) lower than the ground potential GND. For example, the potential level Mid may be set to the ground potential GND. Both the potential levels High and Low may be set to positive potentials or both the potential levels High and Low may be set to negative potentials, so as to reduce the circuit scale.

Alternatively, the transfer portions 303 and 306 may be connected to different transfer nodes and the ON/OFF states of the transfer portions 303 and 306 may be controlled by using transfer signals independent of each other. In one embodiment, the transfer portions 303 and 306 are connected to the same transfer node 218 and the same transfer signal TX1 is input to the gate electrodes of the transfer portions 303 and 306. Accordingly, the accuracy of timing control of ON/OFF states of the transfer portions 303 and 306 can be enhanced. Furthermore, since the transfer portions 303 and 306 can be driven by the same driving circuit and wiring line, the configuration of the photoelectric conversion device 11 can be simplified.

In the above-described manner, the collection node 207 is connected to the cathode 201 via the transfer portion 303. Also, the collection node 210 is connected to the anode 202 via the transfer portion 306.

The collection node 207 may be connected to the cathode 201 without via an active element such as the transfer portion 303. Also, the collection node 210 may be connected to the anode 202 without via an active element such as the transfer portion 306. For example, by maintaining an appropriate relationship between the potential at the photoelectric conversion portion 301 and that at the capacitor portion 307, the electrons generated by the photoelectric conversion portion 301 can be collected to the collection node 207 even if the transfer portion 303 is omitted. Also, by maintaining an appropriate relationship between the potential at the photoelectric conversion portion 302 and that at the capacitor portion 310, the holes generated by the photoelectric conversion portion 302 can be collected to the collection node 210 even if the transfer portion 306 is omitted. Furthermore, the photoelectric conversion portion 301 may be configured to also function as the capacitor portion 307 having a capacitance corresponding to the junction capacitance thereof, and the photoelectric conversion portion 302 may be configured to also function as the capacitor portion 310 having a capacitance corresponding to the junction capacitance thereof. For example, a high concentration region where the n-type impurity concentration is higher than in the other region may be provided in part of the n-type semiconductor region of the photodiode, and the high concentration region may be used as a collection node. As an alternative of switching between transfer and non-transfer of charge from the photoelectric conversion portions 301 and 302 by the transfer portions 303 and 306, switching between discharge and non-discharge of charge from the photoelectric conversion portions 301 and 302 from discharge portions connected to the photoelectric conversion portions 301 and 302 may be used. However, switching between transfer and non-transfer of charge using the transfer portions 303 and 306 enables accurate control of charge compared to the case of not using the transfer portions 303 and 306.

A reference potential supply portion 411 is connected to the anode 211 of the photoelectric conversion portion 301 and the reference node 217 of the capacitor portion 307. A reference potential VF1 is supplied in common from the reference potential supply portion 411 to the anode 211 of the photoelectric conversion portion 301 and the reference node 217 of the capacitor portion 307. A reference potential supply portion 412 is connected to the cathode 212 of the photoelectric conversion portion 302 and the reference node 200 of the capacitor portion 310. A reference potential VF2 is supplied in common from the reference potential supply portion 412 to the cathode 212 of the photoelectric conversion portion 302 and the reference node 200 of the capacitor portion 310.

As described above, the photoelectric conversion portion 301 also generates holes, but the holes are discharged toward the anode 211. The photoelectric conversion portion 302 also generates electrons, but the electrons are discharged toward the cathode 212.

The collection node 207 of the capacitor portion 307 and the collection node 210 of the capacitor portion 310 are connected in common to a detection node 220. A potential corresponding to the amount of electrons transferred from the photoelectric conversion portion 301 to the capacitor portion 307 and the capacitance of the capacitor portion 307 appears at the collection node 207 and the detection node 220. Also, a potential corresponding to the amount of holes transferred from the photoelectric conversion portion 302 to the capacitor portion 310 and the capacitance of the capacitor portion 310 appears at the collection node 210 and the detection node 220. As a result, a potential that is the combination of the potential that may appear at the detection node 220 due to the electrons collected by the collection node 207 and the potential that may appear at the detection node 220 due to the holes collected by the collection node 210 appears at the detection node 220.

The collection nodes 207 and 210 are electrically connected to each other. The electrical connection between the collection nodes 207 and 210 is established by a conductor (electrical conductor). Typically, the collection nodes 207 and 210 are directly connected to each other via a conductor. The conductor has a conductivity of 10⁴ S/m or more (a resistivity of 10⁻⁴ Ω·m or less). An insulator has a conductivity of 10⁻⁷ S/m or less (a resistivity of 10⁷ Ω·m or more). A semiconductor has a conductivity between 10⁻⁷ S/m and 10⁴ S/m (a resistivity between 10⁻⁴ Ω·m and 10⁷ Ω·m). Examples of the conductor include metal, metal compound, graphite, and polysilicon. Silicon with a high impurity concentration (10¹⁹/cm³ or more) is also considered to have conductive behavior. Since the collection nodes 207 and 210 are connected to each other via a conductor, charge is smoothly transmitted and received between the collection nodes 207 and 210. This shortens the time until the potentials at the collection nodes 207 and 210 become static.

It is considered that the following phenomenon will occur transitionally. First, a difference occurs between the amount of electrons collected by the collection node 207 and the amount of holes collected by the collection node 210. In accordance with this difference, a potential difference occurs between the collection nodes 207 and 210. Electrons move between the collection nodes 207 and 210 via the conductor so as to reduce the potential difference. Then, the electrons and holes are recombined (pair annihilation) at the collection node 210. Accordingly, a potential corresponding to the amount of charge as a difference between the amount of electrons collected by the collection node 207 and the amount of holes collected by the collection node 210 appears as a detection potential VD1 at the detection node 220.

In this example, since the collection nodes 207 and 210 are directly connected to each other via the conductor, the potentials at the collection nodes 207 and 210 and the detection node 220 can be regarded as the same. Also, for example, a switch may be provided between the collection node 207 and the detection node 220 and/or between the collection node 210 and the detection node 220. Accordingly, driving can be temporarily performed so that at least two of the collection nodes 207 and 210 and the detection node 220 have different potentials.

The potential at the detection node 220 is represented by VW1, the potential at the collection node 207 is represented by VE1, and the potential at the collection node 210 is represented by VH1. Here, the individual potentials VW1, VE1, and VH1 are variable potentials. As described above, in the embodiment, the collection nodes 207 and 210 are connected in common to the detection node 220 and thus VW1≈VE1≈VH1 is satisfied. In view of the ease of collecting the electrons of the cathode 201 of the photoelectric conversion portion 301 by the collection node 207, VF1<VE1 is to be satisfied. Also, in view of the ease of collecting the holes of the anode 202 of the photoelectric conversion portion 302 by the collection node 210, VH1<VF2 is to be satisfied. Regarding VF1<VE1 and VH1<VF2, VF1<VF2 is satisfied because VE1=VH1. Such a relationship in which the reference potential VF2 is higher than the reference potential VF1 (VF1<VF2) is more beneficial to increase the ranging accuracy than a relationship in which the reference potential VF2 is equal to or lower than the reference potential VF1 (VF1≧VF2). In this way, the efficiency of collecting charge increases, and also high-speed operation and highly accurate signal acquisition can be realized. From a practical point of view, in one embodiment, the potential difference between the reference potentials VF1 and VF2 is 0.10 V or more. For this purpose, the reference potential supply portions 411 and 412 are separately provided in this example. The potential difference between the reference potentials VF1 and VF2 is typically 1 V or more and 5 V or less. The reference potential VF1 may be set to be lower than the ground potential GND of 0 V (VF1<GND) and the reference potential VF2 may be set to be higher than the ground potential GND of 0 V (GND<VF2). That is, the reference potential VF1 may be a negative potential and the reference potential VF2 may be a positive potential.

The detection node 220 is connected to a signal generation portion 315. In this example, the signal generation portion 315 is a MOS transistor (amplification transistor) including a gate, source, and drain. The detection node 220 is connected to the gate of the signal generation portion 315 (amplification transistor).

The drain of the signal generation portion 315 is connected to a power supply portion 432, and a power supply potential VDD is supplied thereto from the power supply portion 432. The source of the signal generation portion 315 is connected to a constant current source 430 via a MOS transistor (selection transistor) 316, and the signal generation portion 315 constitutes a source follower circuit together with the constant current source 430. At the time of a read operation, a selection signal SL is output from a selection signal supply portion 426 connected to the gate of the selection transistor 316 so that the selection transistor 316 is brought into an ON state. Accordingly, the signal generation portion 315 generates a detection signal XD1 corresponding to the potential VD1 at the detection node 220 and outputs the detection signal XD1 to an output line 431, which is included in the column wiring lines 130 illustrated in FIG. 1B.

A reset potential supply portion 413 is connected in common to the collection nodes 207 and 210 via a MOS transistor (reset transistor) 313. The reset potential supply portion 413 outputs a reset potential VS1. A reset signal RS1 output from a reset signal output portion 423 to the gate of the reset transistor 313 causes the reset transistor 313 to be in an ON state. Accordingly, a potential VS11 corresponding to the reset potential VS1 is supplied from the reset potential supply portion 413 to the collection node 207. That is, the potential VE1 at the collection node 207 becomes equal to the potential VS11 (VE1=VS11). Also, a potential VS12 corresponding to the reset potential VS1 is supplied from the reset potential supply portion 413 to the collection node 210. That is, the potential VH1 at the collection node 210 becomes equal to the potential VS12 (VH1=VS12).

At the time of a reset operation, the potential VS11 is supplied to the collection node 207 of the capacitor portion 307, and thereby the electrons held by the capacitor portion 307 are discharged to the reset potential supply portion 413. The potential VS12 is supplied to the collection node 210 of the capacitor portion 310, and thereby the holes held by the capacitor portion 310 are discharged to the reset potential supply portion 413.

To enhance the ranging accuracy, it is beneficial that the potential difference between the potential VS11 and the potential VS12 be less than 0.10 V, compared to a case where the potential difference therebetween is 0.10 V or more. When the potential difference between the potentials VS11 and VS12 is less than 0.10 V regarding the collection nodes 207 and 210 connected in common to the detection node 220, an operation in the accumulation period Tac after the reset period Trs can be stabilized. To make the potential difference between the potentials VS11 and VS12 less than 0.10 V, the collection nodes 207 and 210 may be connected to each other via a conductor having a high conductivity. Also, to make the potential difference between the potentials VS11 and VS12 less than 0.10 V, a resistor that causes the difference between the potentials VS11 and VS12 to be 0.10 V or more may not be located between the collection nodes 207 and 210. Note that a slight potential difference of less than 0.10 V that may be caused by an inevitably generated resistance or manufacturing error is allowable.

In this example, the potential VS11 is applied to the collection node 207 and at the same time the potential VS12 is applied to the collection node 210. A switch may be provided between the reset signal output portion 423 and the collection node 207 and between the reset signal output portion 423 and the collection node 210. In this case, the timing to apply the potential VS11 to the collection node 207 may be different from the timing to apply the potential VS12 to the collection node 210.

In one embodiment, the potential VS11 is higher than the reference potential VF1 (VF1<VS11). In this case, the efficiency of collecting electrons by the collection node 207 after the reset period Trs can be enhanced. Also, in one embodiment, the potential VS12 is lower than the reference potential VF2 (VS12<VF2). In this case, the efficiency of collecting holes by the collection node 210 after the reset period Trs can be enhanced. As described above, when VS11=VS12=VS1 is satisfied, the reset potential VS1 is a potential between the reference potential VF1 and the reference potential VF2 (VF1<VS1<VF2) in order to satisfy both VF1<VS11 and VS12<VF2 in one embodiment.

The potential VS11 is to be selected from the range of −5 to +5 V, and in one embodiment, the potential VS11 is to be selected from the range of −2 to +2 V, for example. Also, the potential VS12 is to be selected from the range of −5 to +5 V, and in one embodiment, the potential VS12 is to be selected from the range of −2 to +2 V, for example. The difference between the potential VS11 and the potential VS12 is 0 in one embodiment. The circuit may be designed so as to satisfy VF1<VS11 and VS12<VF2 within the above-described ranges of the reference potentials VF1 and VF2 and within the above-described ranges of the potentials VS11 and VS12.

In the example illustrated in FIG. 3, a transfer portion 304 and a capacitor portion 308 are connected to the photoelectric conversion portion 301 in a manner similar to the transfer portion 303 and the capacitor portion 307. That is, a set of the transfer portion 303 and the capacitor portion 307 and a set of the transfer portion 304 and the capacitor portion 308 are connected in parallel to the photoelectric conversion portion 301. Likewise, a transfer portion 305 and a capacitor portion 309 are connected to the photoelectric conversion portion 302 in a manner similar to the transfer portion 306 and the capacitor portion 310. That is, a set of the transfer portion 306 and the capacitor portion 310 and a set of the transfer portion 305 and the capacitor portion 309 are connected in parallel to the photoelectric conversion portion 302. The transfer portion 304 and the capacitor portion 308 may have a configuration similar to the transfer portion 303 and the capacitor portion 307. The transfer portion 305 and the capacitor portion 309 may have a configuration similar to the transfer portion 306 and the capacitor portion 310.

In this example, the gate electrodes that have an MIS gate structure and that are respectively included in the transfer portions 304 and 305 are connected in common to a transfer node 219. The transfer node 219 is connected to a transfer signal output portion 429. A transfer signal TX2 is input from the transfer signal output portion 429 to the transfer node 219. The transfer portions 304 and 305 have different conductivity types and are provided complementarily. Thus, the transfer portion 305 is in an OFF state (non-conducting state) in a period when the transfer portion 304 is in an ON state (conducting state) in response to the transfer signal TX2, and the transfer portion 305 is in an ON state in a period when the transfer portion 304 is in an OFF state in response to the transfer signal TX2. A threshold may be set so that both the transfer portions 304 and 305 are brought into an OFF state when the transfer node 219 is at a predetermined potential. Such a predetermined potential is determined in accordance with the potential in the semiconductor region in the MIS gate structure and a threshold of the MIS gate structure. The difference between the potential level High that causes the transfer portion 304 to be in an ON state and the potential level Mid that causes the transfer portion 304 to be in an OFF state is, for example, 1 to 5 V. The difference between the potential level Low that causes the transfer portion 305 to be in an ON state and the potential level Mid that causes the transfer portion 305 to be in an OFF state is, for example, 1 to 5 V. The potential level High is set to a potential (positive potential) higher than the ground potential GND (0 V), and the potential level Low is set to a potential (negative potential) lower than the ground potential GND in one embodiment. For example, the potential level Mid may be set to the ground potential GND. Both the potential levels High and Low may be set to a positive potential, or both the potential levels High and Low may be set to a negative potential, so as to reduce the circuit scale. The transfer portions 304 and 305 may be connected to separate transfer nodes, and the ON/OFF state of the transfer portions 304 and 305 may be controlled by using transfer signals independent of each other. In one embodiment, the transfer portions 303 and 304 connected to the photoelectric conversion portion 301 is operated so that the ON and OFF states are reversed with respect to each other, that is, complementarily. Specifically, while the transfer portion 303 is in an ON state in response to the transfer signal TX1, the transfer portion 304 is in an OFF state in response to the transfer signal TX2. While the transfer portion 303 is in an OFF state in response to the transfer signal TX1, the transfer portion 304 is in an ON state in response to the transfer signal TX2. Also, in one embodiment, the transfer portions 305 and 306 connected to the photoelectric conversion portion 302 is operated so that the ON and OFF states are reversed with respect to each other, that is, complementarily. Specifically, while the transfer portion 306 is in an ON state in response to the transfer signal TX1, the transfer portion 305 is in an OFF state in response to the transfer signal TX2. While the transfer portion 306 is in an OFF state in response to the transfer signal TX1, the transfer portion 305 is in an ON state in response to the transfer signal TX2. Accordingly, signal charge from a single photoelectric conversion portion can be transferred alternately by two transfer portions connected to the single photoelectric conversion portion.

The capacitor portion 308 causes the electrons transferred from the photoelectric conversion portion 301 via the transfer portion 304 to be collected to a collection node 208. The capacitor portion 309 causes the holes transferred from the photoelectric conversion portion 302 via the transfer portion 305 to be collected to a collection node 209. The capacitor portions 308 and 309 each have a p-n junction diode structure. The collection node 208 of the capacitor portion 308 is an n-type semiconductor region, and the collection node 209 of the capacitor portion 309 is a p-type semiconductor region. A reference node 228 of the capacitor portion 308 is a p-type semiconductor region, and a reference node 229 of the capacitor portion 309 is an n-type semiconductor region. The reference node 228 is connected to the reference potential supply portion 411 and is supplied with the reference potential VF1. The reference node 229 is connected to the reference potential supply portion 412 and is supplied with the reference potential VF2.

The collection nodes 208 and 209 are connected in common to a reset potential supply portion 414 via a MOS transistor (reset transistor) 314. The reset potential supply portion 414 outputs a reset potential VS2. A reset signal RS2 output from a reset signal output portion 424 causes the reset transistor 314 to be in an ON state. Accordingly, the potentials at the collection nodes 208 and 209 can be set to predetermined reset potentials. The reset transistor 314 may be omitted. In this case, the reset potential VS2 may be supplied to a detection node 230 via the reset transistor 313.

In one embodiment, the potential difference between the reset potential VS1 and the reset potential VS2 is less than 0.10 V and the potential difference between the reset potential VS1 and the reset potential VS2 is 0 V (VS1=VS2). However, a slight potential difference of less than 0.10 V due to inevitable resistance or manufacturing error is allowed. In one embodiment, the reset potential VS1 and the reset potential VS2 are potentials between the reference potential VF1 and the reference potential VF2. For example, the reset potential VS1 may be higher than the reference potential VF1 (VF1<VS1). Also, the reset potential VS3 may be lower than the reference potential VF2 (VS2<VF2). In one embodiment, VF1<VS1=VS2<VS1 is satisfied. If the reset potential VS1 is different from the reset potential VS2, VF1<VS1≦VS2<VF2 is satisfied and VS2−VS1<VF2−VF1 is satisfied. That is, in one embodiment, the difference between the reset potential VS1 and the reset potential VS2 is 0 and is smaller than the difference between the reference potential VF1 and the reference potential VF2. The reset potential VS1 is, for example, −1 to +1 V. In one embodiment, the reset potential VS1 is −0.5 to +0.5 V. The reset potential VS2 is, for example, −1 to +1 V, and in one embodiment, is −0.5 to +0.5 V.

The collection node 208 of the capacitor portion 308 and the collection node 209 of the capacitor portion 309 are connected in common to the detection node 230. A potential corresponding to the amount of electrons transferred from the photoelectric conversion portion 301 to the capacitor portion 308 and the capacitance of the capacitor portion 308 appears at the collection node 208 and the detection node 230. Also, a potential corresponding to the amount of holes transferred from the photoelectric conversion portion 302 to the capacitor portion 309 and the capacitance of the capacitor portion 309 appears at the collection node 209 and the detection node 230. As a result, a potential that is the combination of a potential VE2 that may appear at the detection node 230 due to the electrons collected by the collection node 208 and a potential VH2 that may appear at the detection node 230 due to the holes collected by the collection node 209 appears as a detection potential VD2.

Although the details will be described below, the detection potentials VD1 and VD2 appear as potentials corresponding to the signal light 82 illustrated in FIG. 1A. In particular, if the sensitivities of the photoelectric conversion portions 301 and 302 with respect to the signal light 82 are the same, the detection potentials VD1 and VD2 appear as complementary signals having opposite polarities and having the same absolute values of signal amplitudes. On the other hand, if the sensitivities of the photoelectric conversion portions 301 and 302 with respect to the signal light 82 are different, the detection potentials VD1 and VD2 appear as signals of the same amount having the same polarity corresponding to the difference in sensitivity relative to the case where the sensitivities are the same and having the same absolute values of signal amplitudes. In view of this, with use of the difference between the detection potentials VD1 and VD2 (VD1−VD2), a signal including a reduced component of the ambient light 83 can be obtained even if there is a difference in sensitivity. Furthermore, approximately double the signal intensity can be obtained from the difference between the detection potentials VD1 and VD2 (VD1−VD2). Furthermore, with use of the sum of the detection potentials VD1 and VD2 (VD1+VD2), a signal representing a difference in sensitivity can be obtained.

In the example illustrated in FIG. 3, a signal generation portion 325 is connected to the detection node 230 in a manner similar to the signal generation portion 315. In this example, the signal generation portion 325 is a MOS transistor (amplification transistor) including a gate, source, and drain. The detection node 230 is connected to the gate of the signal generation portion 325 (amplification transistor).

The drain of the signal generation portion 325 is connected to a power supply portion 442, and a power supply potential VDD is supplied thereto from the power supply portion 442. The source of the signal generation portion 325 is connected to a constant current source 440 via a MOS transistor (selection transistor) 326, and the signal generation portion 325 constitutes a source follower circuit together with the constant current source 440. At the time of a read operation, a selection signal SL2 is output from a selection signal supply portion 436 connected to the gate of the selection transistor 326 so that the selection transistor 326 is brought into an ON state. Accordingly, the signal generation portion 325 generates a detection signal XD2 corresponding to the potential VD2 at the detection node 230 and outputs the detection signal XD2 to an output line 441, which is included in the column wiring lines 130 illustrated in FIG. 1B.

Examples of potentials used in the above-described circuit will be described. The ground potential GND is 0 V. In a first example, VS1, VS2=0 V, VF1=−1 V, VF2=+1 V, High=+2 V, Mid=0 V, and Low=−2 V. In a second example, VS1, VS2=+1 V, VF1=0 V, VF2=+2 V, High=+3 V, Mid=+1 V, and Low=−1 V. The second example is obtained by shifting the individual potentials in the first example by S (V) and corresponds to the case where S=−1. In a third example, VS1, VS2=0 V, VF1=−2 V, VF2=+2 V, High=+4 V, Mid=0 V, and Low=−4 V. The third example is an example in which the potentials in the first example are multiplied by T and corresponds to the case where T=2. The above-described value S may be a positive or negative value, and the above-described value T may be less than 1. The second and third examples may be combined, that is, the first example may be shifted by S (V) and multiplied by T. The actual potential values can be appropriately adjusted while maintaining the relationship among values of potentials, the differences in potential, and the relationship among the differences in potential that are grasped from the individual potentials in the foregoing three examples.

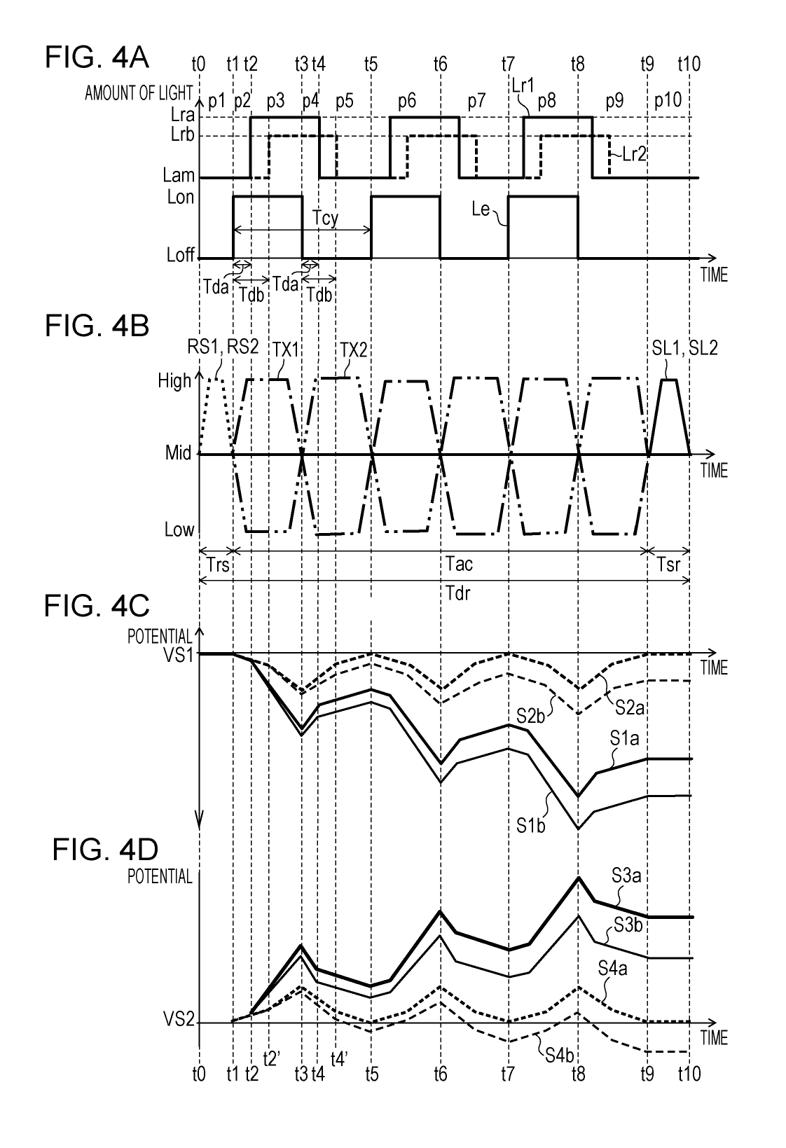

Next, the operation per drive period Tdr of one photoelectric conversion cell 111 of the ranging apparatus 1 will be described with reference to FIGS. 4A to 4D. In the description given below with reference to FIGS. 4A to 4D, periods p1 to p10 correspond to the period from time t0 to time t10.

FIG. 4A illustrates a light emission level Le of the light emitting device 21 and light reception levels Lr1 and Lr2 of the photoelectric conversion device 11. The light emitting device 21 is in an OFF state in the periods p1, p4, p5, p7, and p9 when the light emission level Le corresponds to an amount of light Loff. The light emitting device 21 is in an ON state in the periods p2, p3, p6, and p8 when the light emission level Le corresponds to an amount of light Lon. In this way, the light emitting device 21 repeats blinking in one cycle that corresponds to a period Tcy from time t1 to time t5. Here, it is assumed that blinking is repeated three times for simplifying the description. Actually, however, blinking is repeated 100 to 10000 times within the accumulation period Tac every time ranging is performed, and thereby sufficient accuracy can be ensured.

When the speed of light is represented by c (m/s), a delay time from light emission to light reception based on a distance d (m) from the ranging apparatus 1 to the target 9 is 2×d/c (s). The delay time from light emission to light reception may be detected within one cycle Tcy. The speed of light is 3×10⁸ m/s, that is, 0.3 m/ns. Thus, one cycle Tcy is set to, for example, 1 ns to 1000 ns, and in one embodiment, one cycle Tcy is set to 10 ns to 100 ns. For example, the delay from light emission to light reception corresponding to a distance difference of 0.3 m is 2 ns. Thus, if one cycle Tcy is 10 ns, a distance difference of 0.3 m can be detected by detecting a physical amount corresponding to the delay time within 10 ns. In accordance with the cycle Tcy and the number of times blinking is repeated, one ranging operation is carried out in a short time of 1 μs to 10 ms. Thus, about 10 to 1000 rows of the cell array 110, that is, about 1 to 1000 frames, can be read in one second. For example, if the drive period Tdr for one row is 1 μs, 1000 frames in 1000 rows can be read in one second. If the drive period Tdr for one row is 10 ms, 1 frame in 100 rows can be read in one second.

The amount of light received by the photoelectric conversion device 11 in response to light emission by the light emitting device 21 is represented by Lra and Lrb. The waveform represented by the light reception level Lr1 indicates that light reception is started at time t2, which is the time when a period Tda has elapsed since time t1 when light emission is started, and that light reception is finished at time t4, which is the time when a period Tda has elapsed since time t3 when light emission is finished, in accordance with the distance from the ranging apparatus 1 to the target. The waveform represented by the light reception level Lr2 indicates that light reception is started at time t2′, which is the time when a period Tdb has elapsed since time t1 when light emission is started, and that light reception is finished at time t4′, which is the time when a period Tdb has elapsed since time t3 when light emission is finished, in accordance with the distance from the ranging apparatus 1 to the target. In this example, Tda<Tdb and thus it can be understood that the target that has reflected the signal light represented by the light reception level Lr1 is closer to the ranging apparatus 1 than the target that has reflected the signal light represented by the light reception level Lr2. Furthermore, in this example, Lrb<Lra and thus it can be understood that the signal light represented by the light reception level Lr1 is likely to have a higher reflectance for the target 9 than the signal light represented by the light reception level Lr2.

In the period when the photoelectric conversion device 11 receives light emitted by the light emitting device 21, the amounts of light Lra and Lrb received by the photoelectric conversion device 11 include not only the signal light 82 but also the ambient light 83 illustrated in FIG. 1A. The amount of received ambient light is represented by Lam. Among the amounts of light Lra and Lrb, the amount of light obtained by subtracting Lam therefrom corresponds to signal light having actual distance information.

FIG. 4B illustrates a temporal change in the reset signals RS1 and RS2 (broken line), the selection signals SL1 and SL2 (solid line), the transfer signal TX1 (one-dot chained line), and the transfer signal TX2 (two-dot chained line). The potential level High is higher than the potential level Low, and the potential level Mid is between the potential level High and the potential level Low. The potential level High, the potential level Mid, and the potential level Low may each include potentials in a certain range. For example, the potential level Mid is a potential in a certain range including the ground potential (0 V). In FIG. 4B, the potential at the position where the horizontal axis representing time is located corresponds to the potential level Mid. Regarding FIG. 4B, a description will be given under the assumption that, for convenience, transistors operate similarly to the case where the potential level is High, at a transitional potential between the potential level Mid and the potential level High (at a rising or falling potential). Also, a description will be given under the assumption that the transistors operate similarly to the case where the potential level is Low, at a transitional potential between the potential level Mid and the potential level Low (at a rising or falling potential). The potential levels that cause the individual transistors to be turned ON and OFF are not necessarily the same and may be different from one another.

The reset signals RS1 and RS2 are at the potential level High in the same period, but the periods when the reset signals RS1 and RS2 are at the potential level High may be different from each other. The transfer signals TX1 and TX2 are typically rectangular waves or sine waves with the same cycle in which positive and negative signs are inverted. The cycles of the transfer signals TX1 and TX2 may be identical to the cycle Tcy in which the light emitting device 21 emits light. However, the cycles of the transfer signals may be slightly different from the light emission cycle if a decrease in the ranging accuracy is accepted.

In the period p1 when the reset signals RS1 and RS2 are at a potential higher than the potential level Mid (typically at the potential level High), the reset transistors 313 and 314 are in an ON state. From time t1 to time t10, which is a period when the reset signals RS1 and RS2 are at the potential level Mid, the reset transistors 313 and 314 are in an OFF state. In FIG. 4A, the illustration is given under the assumption that the reset signals RS1 and RS2 are the same. Alternatively, the reset signals RS1 and RS2 may be different from each other in a period that is not illustrated.

In the periods p2, p3, p6, and p8 when the transfer signal TX1 is at a potential higher than the potential level Mid (typically at the potential level High), the transfer portion 303 is in an ON state whereas the transfer portion 306 is in an OFF state. In the periods p4, p5, p7, and p9 when the transfer signal TX1 is at a potential lower than the potential level Mid (typically at the potential level Low), the transfer portion 303 is in an OFF state whereas the transfer portion 306 is in an ON state. The period from when the reset transistors 313 and 314 are changed from an ON state to an OFF state to when one of the transfer portions 303 and 306 is changed to an ON state may be as short as possible.

In the periods p2, p3, p6, and p8 when the transfer signal TX2 is at a potential lower than the potential level Mid (typically at the potential level Low), the transfer portion 305 is in an ON state whereas the transfer portion 304 is in an OFF state. In the periods p4, p5, p7, and p9 when the transfer signal TX2 is at a potential higher than the potential level Mid (typically at the potential level High), the transfer portion 305 is in an OFF state whereas the transfer portion 304 is in an ON state. The period from when the reset transistors 313 and 314 are changed from an ON state to an OFF state to when one of the transfer portions 304 and 305 is changed to an ON state may be as short as possible.

In the period (or at the time) when the transfer signal TX1 is at the potential level Mid, the transfer portions 303 and 306 are in an OFF state. In the period (or at the time) when the transfer signal TX2 is at the potential level Mid, the transfer portions 304 and 305 are in an OFF state. The potential level Mid is determined in accordance with the characteristics of the transfer portions 303, 304, 305, and 306, as described above.

FIG. 4C illustrates a change in the potential at the detection node 220. In a case where a sensitivity K1 of the photoelectric conversion portion 301 and a sensitivity K2 of the photoelectric conversion portion 302 are almost the same (K1≈K2), a potential change Sla represents a change in potential at the light reception level Lr1 and a potential change S2a represents a change in potential at the light reception level Lr2. In a case where the sensitivity K1 of the photoelectric conversion portion 301 and the sensitivity K2 of the photoelectric conversion portion 302 are different (K1<K2), a potential change Slb represents a change in potential at the light reception level Lr1 and a potential change S2b represents a change in potential at the light reception level Lr2.

In the period p1, the potentials at the collection nodes 207 and 210 and the detection node 220 are set to potentials corresponding to the reset potential VS1 (the potentials VS11 and VS12) by the reset potential supply portion 413.

In the period p2, the electrons generated by the photoelectric conversion portion 301 in accordance with the amount of light Lam of the ambient light 83 are transferred to the capacitor portion 307. When electrons are generated by the photoelectric conversion portion 301, the potential at the cathode 201 becomes higher than the potential at the anode 211. If the potential at the anode 211 is, for example, VF1=−2 V, the potential at the cathode 201 is about −1 V. The reset potential VS1 makes the potential at the collection node 207 higher than the potential at the anode 211 (VF1<VS1). Thus, when the transfer portion 303 is in an ON state, electrons that have been generated quickly move to the collection node 207 at which the potential is higher than that at the cathode 201. In accordance with the transfer of the electrons, the potential at the detection node 220 connected to the collection node 207 decreases.

In the period p3, the electrons generated by the photoelectric conversion portion 301 in accordance with the amount of light Lra including the signal light 82, which is larger than the amount Lam of the ambient light 83, are transferred to the capacitor portion 307. In accordance with the transfer of the electrons, the potential at the detection node 220 connected to the collection node 207 decreases with a larger gradient than in the period p2. This is because the amount of received light per unit time increases by the amount of the signal light 82.

In the period p4, the holes generated by the photoelectric conversion portion 302 in accordance with the amount of light Lra including the signal light 82, which is larger than the amount Lam of the ambient light 83, are transferred to the capacitor portion 310. In accordance with the transfer of the holes, the potential at the detection node 220 connected to the collection node 210 increases.

In the periods p2 and p3, the transfer portion 305 is in an ON state. Thus, the holes generated by the photoelectric conversion portion 302 in the periods p2 and p3 are transferred to the capacitor portion 309 in the periods p2 and p3. Thus, among the holes transferred to the capacitor portion 310 after the transfer portion 306 is turned ON at time t3, for example, in the period p4, the amount of holes generated by the photoelectric conversion portion 302 in the period p4 is larger than the amount of holes generated by the photoelectric conversion portion 302 in the periods p2 and p3. Ideally, the holes generated by the photoelectric conversion portion 302 in the periods p2 and p3 are not transferred to the capacitor portion 310 in the period p4.

In the period p5, the holes generated by the photoelectric conversion portion 302 in accordance with the amount Lam of the ambient light 83 are transferred to the capacitor portion 310. In accordance with the transfer of the holes, the potential at the detection node 220 connected to the collection node 210 increases.

The same operation is repeated in the periods p6, p7, p8, and p9. In the periods p4 and p5, the transfer portion 304 is in an ON state. Thus, the electrons generated by the photoelectric conversion portion 301 in the periods p4 and p5 are transferred to the capacitor portion 308 in the periods p4 and p5. Thus, among the electrons transferred to the capacitor portion 307 after the transfer portion 303 is turned ON at time t5, for example, in the period p6, the amount of electrons generated by the photoelectric conversion portion 301 in the period p6 is larger than the amount of electrons generated by the photoelectric conversion portion 301 in the periods p4 and p5. Ideally, the electrons generated by the photoelectric conversion portion 301 in the periods p4 and p5 are not transferred to the capacitor portion 307 in the period p6.

With such a cycle Tcy being repeated several times, a signal suitable for ranging from which the component of the ambient light 83 has been removed and in which the component of the signal light 82 is integrated can be obtained.

Regarding the light reception level Lr1, the delay time Tda is less than a quarter of the cycle Tcy (Tda<Tcy/4). Thus, the potential at the detection node 220 is effectively dominated by the electrons transferred in the period p3, and the potential at the detection node 220 becomes lower than the reset potential VS1 (the absolute value increases). If the delay time Tdb is a quarter of the cycle Tcy as in the light reception level Lr2 (Tdb=Tcy/4), the amount of electrons and the amount of holes transferred to the collection nodes 207 and 210 within one cycle Tcy are equal to each other. Thus, the potential at the detection node 220 is equal to the reset potential VS1. If the delay time Tda>Tcy/4, the potential at the detection node 220 is effectively dominated by the holes transferred in the period p4, and the potential at the detection node 220 becomes higher than the reset potential VS1 (the absolute value increases).

Here, the ON period and OFF period of the light emitting device 21 in one cycle Tcy are equal to each other, but the ON period and OFF period may be different from each other. If the ON period and OFF period are different from each other, the signal output from the signal generation portion 315 may be corrected on the basis of the difference between the ON period and the OFF period. Furthermore, although the ON period and OFF period of the transfer gate in one cycle Tcy are equal to each other here, the ON period and OFF period may be different from each other. If the ON period and OFF period are different from each other, the signal output from the signal generation portion 315 may be corrected on the basis of the difference between the ON period and the OFF period.

If the sensitivity K1 of the photoelectric conversion portion 301 is lower than the sensitivity K2 of the photoelectric conversion portion 302 (K1<K2), the amount of holes generated by the photoelectric conversion portion 302 is larger than the amount of electrons generated by the photoelectric conversion portion 301 under the same amount of light. Thus, the potential at the detection node 220 further increases if the sensitivity K1 is equal to the sensitivity K2.

Referring to FIG. 4D, in a case where the sensitivity K1 of the photoelectric conversion portion 301 and the sensitivity K2 of the photoelectric conversion portion 302 are almost the same (K1≈K2), a potential change S3a represents a change in potential at the light reception level Lr1 and a potential change S4a represents a change in potential at the light reception level Lr2. In a case where the sensitivity K1 of the photoelectric conversion portion 301 and the sensitivity K2 of the photoelectric conversion portion 302 are different (K1<K2), a potential change S3b represents a change in potential at the light reception level Lr1 and a potential change S4b represents a change in potential at the light reception level Lr2.

In the period p1, the potentials at the collection nodes 208 and 209 and the detection node 230 are set to potentials corresponding to the reset potential VS2 (the potentials VS21 and VS22) by the reset potential supply portion 414.

In the period p2, the holes generated by the photoelectric conversion portion 302 in accordance with the amount of light Lam of the ambient light 83 are transferred to the capacitor portion 309. When holes are generated by the photoelectric conversion portion 302, the potential at the anode 202 becomes lower than the potential at the cathode 212. If the potential at the cathode 212 is, for example, VF2=+2 V, the potential at the anode 202 is about +1 V. The reset potential VS2 makes the potential at the collection node 209 lower than the potential at the cathode 212 (VF2>VS2). Thus, when the transfer portion 305 is in an ON state, holes that have been generated quickly move to the collection node 209 at which the potential is lower than that at the anode 202. In accordance with the transfer of the holes, the potential at the detection node 230 connected to the collection node 209 increases.

In the period p3, the holes generated by the photoelectric conversion portion 302 in accordance with the amount of light Lra including the signal light 82, which is larger than the amount Lam of the ambient light 83, are transferred to the capacitor portion 309. In accordance with the transfer of the holes, the potential at the detection node 230 connected to the collection node 209 increases with a larger gradient than in the period p2. This is because the amount of received light per unit time increases by the amount of the signal light 82.

In the period p4, the holes generated by the photoelectric conversion portion 302 in accordance with the amount of light Lra including the signal light 82, which is larger than the amount Lam of the ambient light 83, are transferred to the capacitor portion 310. In accordance with the transfer of the holes, the potential at the detection node 220 connected to the collection node 210 increases.

In the periods p2 and p3, the transfer portion 303 is in an ON state. Thus, the electrons generated by the photoelectric conversion portion 301 in the periods p2 and p3 are transferred to the capacitor portion 307 in the periods p2 and p3. Thus, among the electrons transferred to the capacitor portion 308 after the transfer portion 304 is turned ON at time t3, for example, in the period p4, the amount of electrons generated by the photoelectric conversion portion 301 in the period p4 is larger than the amount of electrons generated by the photoelectric conversion portion 301 in the periods p2 and p3. Ideally, the electrons generated by the photoelectric conversion portion 301 in the periods p2 and p3 are not transferred to the capacitor portion 308 in the period p4.

In the period p5, the electrons generated by the photoelectric conversion portion 301 in accordance with the amount Lam of the ambient light 83 are transferred to the capacitor portion 308. In accordance with the transfer of the electrons, the potential at the detection node 230 connected to the collection node 208 decreases.

The same operation is repeated in the periods p6, p7, p8, and p9. In the periods p4 and p5, the transfer portion 306 is in an ON state. Thus, the holes generated by the photoelectric conversion portion 302 in the periods p4 and p5 are transferred to the capacitor portion 310 in the periods p4 and p5. Thus, among the holes transferred to the capacitor portion 309 after the transfer portion 305 is turned ON at time t5, for example, in the period p6, the amount of holes generated by the photoelectric conversion portion 302 in the period p6 is larger than the amount of holes generated by the photoelectric conversion portion 302 in the periods p4 and p5. Ideally, the holes generated by the photoelectric conversion portion 302 in the periods p4 and p5 are not transferred to the capacitor portion 309 in the period p6.

A quantitative description will be given of a potential at the detection node 220 in FIG. 4C, regarding the case where the sensitivity K1 of the photoelectric conversion portion 301 and the sensitivity K2 of the photoelectric conversion portion 302 are almost the same (K1≈K2). Among the electrons serving as signal charge, a component derived from the ambient light 83 is represented by (−N), and a component derived from the signal light 82 is represented by (−S). Among the holes serving as signal charge, a component derived from the ambient light 83 is represented by (+N), and a component derived from the signal light 82 is represented by (+S). A coefficient proportional to the length of the period p2 is represented by a, a coefficient proportional to the length of the period p3 is represented by b, a coefficient proportional to the length of the period p4 is represented by c, and a coefficient proportional to the length of the period p5 is represented by d. N and S may be regarded as an amount of charge generated per unit time, and a, b, c, and d may be regarded as a length of time period for generating charge.

First, under the assumption that recombination of electrons and holes does not occur at the detection node 220, the amounts of charge at the collection nodes 207 and 210 are calculated. An increase in the amount of charge at the collection node 207 in the period p2 is expressed by a×(−N), and the amount of charge at the collection node 207 at time t2 is expressed by a×(−N). On the other hand, an increase in the amount of charge at the collection node 210 in the period p2 is 0, and the amount of charge at the collection node 210 at time t2 is 0. An increase in the amount of charge at the collection node 207 in the period p3 is expressed by b×(−N−S), and the amount of charge at the collection node 207 at time t3 is expressed by a×(−N)+b×(−N−S). On the other hand, an increase in the amount of charge at the collection node 210 in the period p3 is 0, and the amount of charge at the collection node 210 at time t3 is 0. An increase in the amount of charge at the collection node 207 in the period p4 is 0, and the amount of charge at the collection node 207 at time t4 is expressed by a×(−N)+b×(−N−S). An increase in the amount of charge at the collection node 210 in the period p4 is expressed by c×(+N+S), and the amount of charge at the collection node 210 at time t4 is expressed by c×(+N+S). An increase in the amount of charge at the collection node 207 in the period p5 is 0, and the amount of charge at the collection node 207 at time t5 is expressed by a×(−N)+b×(−N−S). On the other hand, an increase in the amount of charge at the collection node 210 in the period p5 is expressed by d×(+N), and the amount of charge at the collection node 210 at time t5 is expressed by c×(+N+S)+d×(+N).

An actual amount of charge at the detection node 220 at time t5 corresponds to that obtained by subtracting electrons and holes, which is expressed by the following expression: VD1=a×(−N)+b×(−N−S)+c×(+N+S)+d×(+N)=(a+b)×(−N)+(c+d)×(+N)+b×(−S)+c×(+S)=((c+d)−(a+b))×N+(c−b)×S.

(a+b) corresponds to the period from time t1 to time t3 (the periods p2 and p3) in which the electrons to be collected to the collection node 207 are generated by the photoelectric conversion portion 301 and the holes to be collected to the collection node 209 are generated by the photoelectric conversion portion 302. (c+d) corresponds to the period from time t3 to time t5 (the periods p4 and p5) in which the electrons to be collected to the collection node 208 are generated by the photoelectric conversion portion 301 and the holes to be collected to the collection node 210 are generated by the photoelectric conversion portion 302.

The detection potential VD1 is based on the electrons that are generated by the photoelectric conversion portion 301 and collected to the collection node 207 in the period from time t1 to time t3, and the holes that are generated by the photoelectric conversion portion 302 and collected to the collection node 210 in the period from time t3 to time t5. The detection potential VD2 is based on the holes that are generated by the photoelectric conversion portion 302 and collected to the collection node 209 in the period from time t1 to time t3, and the electrons that are generated by the photoelectric conversion portion 301 and collected to the collection node 208 in the period from time t3 to time t5. Of course, the period from time t1 to time t3 and the period from time t3 to time t5 are different from each other. However, the charges to be collected are simultaneously generated by both the photoelectric conversion portions 301 and 302 in the two periods. Thus, the potentials at the detection nodes 220 and 230 may be regarded as potentials based on charges that complement each other.

In the period from time t1 to time t5, if the ambient light 83 is constant and if the periods when the transfer portions 303 and 306 are complementarily in an ON state are the same, (c+d)−(a+b)=0 is satisfied. Thus, it is understood that the potential that appears at the detection node 220 at time t5 is obtained as a signal which is (c−b)×S from which at least part of the component of the ambient light 83 has been removed and which indicates only the component of the signal light 82. Even if (c+d)−(a+b)=0 is not satisfied, that is, even if the duty ratio of the transfer signals TX1 and TX2 is not 0.5, the N component can be reduced as much as possible by making the duty ratio closer to 0.5. The duty ratio of the transfer signals TX1 and TX2 may be 0.50, and may be in the range from 0.25 to 0.75 in one embodiment, or may be in the range from 0.40 to 0.60 in another embodiment. In other words, ⅓≦(c+d)/(a+b)≦3 may be satisfied in one embodiment, or ⅔≧(c+d)/(a+b)≦3/2 may be satisfied in another embodiment. That is, the ratio between the length of the period corresponding to (a+b) and the length of the period corresponding to (c+d) may be ⅔ or more and 3/2 or less.

Next, a quantitative description will be given of a potential at the detection node 220, regarding the case where the sensitivity K1 of the photoelectric conversion portion 301 and the sensitivity K2 of the photoelectric conversion portion 302 are different (K1<K2 or K1>K2). A coefficient proportional to a sensitivity difference (sensitivity ratio) with respect to the case where the sensitivities are the same is presented by r (=K2/K1). That is, among the electrons serving as signal charge, a component derived from the ambient light 83 is represented by (−N), and a component derived from the signal light 82 is represented by (−S). Among the holes serving as signal charge, a component derived from the ambient light 83 is represented by r×(+N), and a component derived from the signal light 82 is represented by r×(+S).

Likewise, an increase in the amount of charge at the collection node 207 in the period p2 is expressed by a×(−N), and the amount of charge at the collection node 207 at time t2 is expressed by a×(−N). On the other hand, an increase in the amount of charge at the collection node 210 in the period p2 is 0, and the amount of charge at the collection node 210 at time t2 is 0. An increase in the amount of charge at the collection node 207 in the period p3 is expressed by b×(−N−S), and the amount of charge at the collection node 207 at time t3 is expressed by a×(−N)+b×(−N−S). On the other hand, an increase in the amount of charge at the collection node 210 in the period p3 is 0, and the amount of charge at the collection node 210 at time t3 is 0. An increase in the amount of charge at the collection node 207 in the period p4 is 0, and the amount of charge at the collection node 207 at time t4 is expressed by a×(−N)+b×(−N−S). An increase in the amount of charge at the collection node 210 in the period p4 is expressed by c×r×(+N+S), and the amount of charge at the collection node 210 at time t4 is expressed by c×r×(+N+S). An increase in the amount of charge at the collection node 207 in the period p5 is 0, and the amount of charge at the collection node 207 at time t5 is expressed by a×(−N)+b×(−N−S). On the other hand, an increase in the amount of charge at the collection node 210 in the period p5 is expressed by d×r×(+N), and the amount of charge at the collection node 210 at time t5 is expressed by c×r×(+N+S)+d×r×(+N).

An actual amount of charge at the detection node 220 at time t5 corresponds to that obtained by subtracting electrons and holes, which is expressed by the following expression: VD1=a×(−N)+b×(−N−S)+c×r×(+N+S)+d×r×(+N)=(a+b)×(−N)+(c+d)×r×(+N)+b×(−S)+c×r×(+S)={(c+d)×r−(a+b)}×N+(c×r−b)×S.

In the period from time t1 to time t5, if the ambient light 83 is constant and if the periods when the transfer portions 303 and 306 are complementarily in an ON state are the same, (c+d)−(a+b)=0 is satisfied. Thus, it is understood that the potential that appears at the detection node 220 at time t5 is obtained as a signal expressed by (r−1)×(a+b)×N+(c×r−b)×S, which is part of the component of the ambient light 83 and a component of the signal light 82. This result indicates that the N component can be removed on the basis of (c+d)−(a+b)=0 when S1=S2 and that the N component remains when S1<S2.

A quantitative description will be given of a potential at the detection node 230 in FIG. 4D, regarding the case where the sensitivity K1 of the photoelectric conversion portion 301 and the sensitivity K2 of the photoelectric conversion portion 302 are different from each other (K1<K2 or K1>K2).

An increase in the amount of charge at the collection node 208 in the period p2 is 0, and the amount of charge at the collection node 208 at time t2 is 0. On the other hand, an increase in the amount of charge at the collection node 209 in the period p2 is expressed by a×r×(+N), and the amount of charge at the collection node 209 at time t2 is expressed by a×r×(+N). An increase in the amount of charge at the collection node 208 in the period p3 is 0, and the amount of charge at the collection node 208 at time t3 is 0. On the other hand, an increase in the amount of charge at the collection node 209 in the period p3 is expressed by b×r×(+N+S), and the amount of charge at the collection node 209 at time t3 is expressed by a×r×(+N)+b×(+N+S). An increase in the amount of charge at the collection node 208 in the period p4 is expressed by c×(−N−S), and the amount of charge at the collection node 208 at time t4 is expressed by c×(−N−S). An increase in the amount of charge at the collection node 209 in the period p4 is 0, and the amount of charge at the collection node 209 at time t4 is expressed by a×r×(+N)+b×r×(+N+S). An increase in the amount of charge at the collection node 208 in the period p5 is expressed by d×(−N), and the amount of charge at the collection node 208 at time t5 is expressed by c×(−N−S)+d×(−N). On the other hand, an increase in the amount of charge at the collection node 209 in the period p5 is 0, and the amount of charge at the collection node 209 at time t5 is expressed by a×r×(+N)+b×r×(+N+S).

An actual amount of charge at the detection node 230 at time t5 corresponds to that obtained by subtracting electrons and holes, which is expressed by the following expression: c×(−N−S)+d×(−N)+a×r×(+N)+b×r×(+N+S)=(c+d)×(−N)+(a+b)×r×(+N)+c×(−S)+b×r×(+S)={(a+b)×r−(c+d)}×N+(b×r−c)×S.

In the period from time t1 to time t5, if the ambient light 83 is constant and if the periods when the transfer portions 304 and 305 are complementarily in an ON state are the same, (c+d)−(a+b)=0 is satisfied. Thus, it is understood that the potential that appears at the detection node 230 at time t5 is obtained as a signal expressed by (r−1)×(a+b)×N+(b×r−c)×S, which is part of the component of the ambient light 83 and a component of the signal light 82. This result indicates that the N component can be removed on the basis of (c+d)−(a+b)=0 when S1=S2 and that the N component remains when S1<S2.

In contrast, the difference between the detection potentials VD1 and VD2 (VD1−VD2) is expressed as follows: VD1−VD2={(c+d)×r−(a+b)}×N+(c×r−b)×S−{(a+b)×r−(c+d)}×N−(b×r−c)×S=(1+r)[{(c+d)−(a+b)}×N+(c−b)×S].

In the period from time t1 to time t5, if the ambient light 83 is constant and if the periods when the transfer portions 304 and 305 are complementarily in an ON state are the same, (c+d)−(a+b)=0 is satisfied. Thus, the difference between the potential that appears at the detection node 220 at time t5 and the potential that appears at the detection node 230 at time t5 is expressed by VD1−VD2=(1+r)×(c−d)×S. This means that, as a result of obtaining the difference between the detection potentials VD1 and VD2, the component (N) of the ambient light 83 can be removed or reduced even if there is a difference in sensitivity. That is, as a result of obtaining a signal correlated with VD1−VD2, a signal corresponding to an accurate signal light 82 in which a sensitivity difference between photoelectric conversion portions and an influence of the ambient light 83 are reduced can be obtained.

The sum of the detection potentials VD1 and VD2 (VD1+VD2) is expressed as follows: VD1+VD2={(c+d)×r−(a+b)}×N+(c×r−b)×S+{(a+b)×r−(c+d)}×N+(b×r−c)×S=(r−1)[{(a+b+c+d)}×N+(b+c)×S]. (a+b+c+d) and (b+c) are constants P determined in accordance with the duty ratio of the transfer signals TX1 and TX2. That is, VD1+VD2=(r−1)×P includes information representing the sensitivity difference (sensitivity ratio) between the sensitivity K1 of the photoelectric conversion portion 301 and the sensitivity K2 of the photoelectric conversion portion 302, regarding a potential that appears at the detection node 220. That is, with use of information correlated with VD1+VD2 as a correction value for the sensitivity difference between photoelectric conversion portions, information about accurate signal light 82 in which a sensitivity difference between photoelectric conversion portions and an influence of the ambient light 83 are reduced can be obtained.

If the sensitivity K1 of the photoelectric conversion portion 301 and the sensitivity K2 of the photoelectric conversion portion 302 are different from each other (K1<K2), a=b=c=d is satisfied if the delay time Tdb is ¼ of the cycle Tcy (Tdb=Tcy/4). Thus, VD1=VD2=2×(r−1)×a×N+(r−1)×a×S is satisfied, and the same output is obtained. In this case, (VD1−VD2) is 0, and VDM=((VD1+VD2)/2) is 2×(r−1)×a×N+(r−1) a×S. The difference between VD1 and VDM (VD1−VDM) is 0.

For example, if the delay time Tdb is ⅛ of the cycle Tcy (Tdb=Tcy/8), 3a=b=3c=d is satisfied, and thus VD1=4×(r−1)×a×N+(r−3)×a×S, and VD2=4×(r−1)×a×N+(3r−1)×a×S. As a result, output of the same amounts is obtained for the component of the ambient light 83, and output of different amounts is obtained for the signal light 82. In this case, the difference (VD1−VD2) is 2×(1+r)×a×S, and VDM=(0.5×(VD1+VD2)) is 4×(r+1)×a×N+2×(r+1)×a×S. Furthermore, the difference between VD1 and VDM (VD1−VDM) is 2×(1+r)×a×S.

Here, since a and r are coefficients, the difference between VD1 and VD2 (VD1−VD2) or the difference between VD1 and VDM (VD1−VDM) can be obtained as a value proportional to the signal light 82, on the basis of the case where the delay time Tdb is ¼ of the cycle Tcy.

In this way, the component of the ambient light 83 can be removed or reduced by using the detection node 230 also in a case where there is a difference between the sensitivity K1 of the photoelectric conversion portion 301 and the sensitivity K2 of the photoelectric conversion portion 302. Thus, a signal suitable for ranging can be obtained even if the component of the signal light 82 is integrated.

In the example illustrated in FIG. 3, the signal generation portion 315 outputs the detection signal XD1, which indicates the signal level LD1 based on the detection potential VD1 at the detection node 220, to the output line 431. Also, the signal generation portion 325 outputs the detection signal XD2, which indicates the signal level LD2 based on the detection potential VD2 at the detection node 230, to an output line 441. The ranging apparatus 1 generates a difference signal representing a difference between the signal levels LD1 and LD2 by using the detection signals XD1 and XD2. The difference signal serves as a signal correlated with a difference between the detection potentials VD1 and VD2 (VD1−VD2).

The signal correlated with the difference between the detection potentials VD1 and VD2 (VD1−VD2) can be obtained by a differential circuit. As a differential circuit, a differential amplifier circuit may be used as an analog circuit or a subtraction circuit may be used as a digital circuit. It is difficult to provide a differential circuit in the typical photoelectric conversion cell 111 due to layout restrictions. Thus, the differential circuit may be provided in the signal processing part 160 in the photoelectric conversion device 11 (see FIG. 1B). In a case where the differential circuit is provided in the signal processing part 160 in the photoelectric conversion device 11, the differential circuit receives the detection signals XD1 and XD2 and outputs the difference between the detection signals XD1 and XD2. Alternatively, the differential circuit may be provided in the processing unit 40 outside the photoelectric conversion device 11. An AD conversion circuit may be provided in the photoelectric conversion device 11. In this case, the detection signals may be converted into digital signals and then the difference between the digital signals may be calculated.

Also, the ranging apparatus 1 may generate a sum signal representing a sum of the signal levels LD1 and LD2 by using the detection signals XD1 and XD2. The sum signal serves as a signal correlated with a sum of the detection potentials VD1 and VD2 (VD1+VD2).

The signal correlated with the sum of the detection potentials VD1 and VD2 (VD1+VD2) can be obtained by an addition circuit by using the detection signals XD1 and XD2. Either an analog circuit or digital circuit may be used as the addition circuit. It is difficult to provide an addition circuit in the typical photoelectric conversion cell 111 due to layout restrictions. Thus, the addition circuit may be provided in the signal processing part 160 in the photoelectric conversion device 11 (see FIG. 1B). In a case where the addition circuit is provided in the signal processing part 160 in the photoelectric conversion device 11, the addition circuit receives the detection signals XD1 and XD2 and outputs the sum of the detection signals XD1 and XD2. Alternatively, the addition circuit may be provided in the processing unit 40 outside the photoelectric conversion device 11. An AD conversion circuit may be provided in the photoelectric conversion device 11. In this case, the detection signals may be converted into digital signals and then the sum of the digital signals may be calculated.

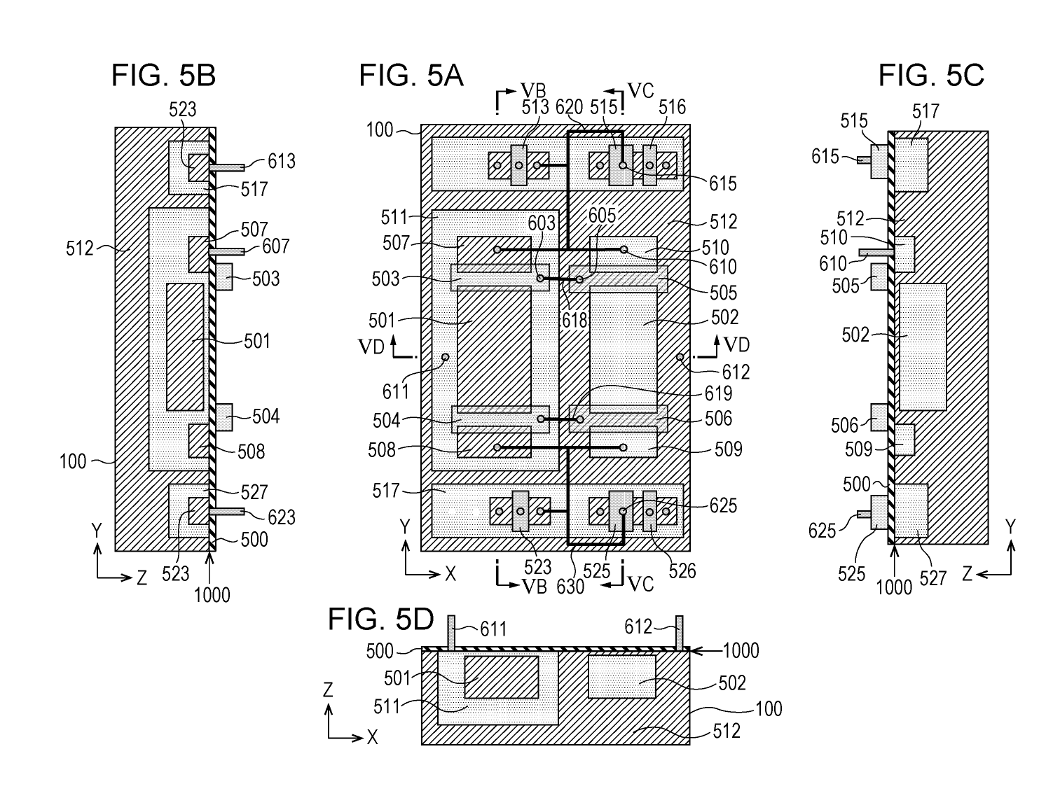

FIGS. 5A to 5D illustrate an example layout of the photoelectric conversion cell 111. FIG. 5A is a schematic plan view of the photoelectric conversion cell 111. FIG. 5B is a schematic cross-sectional view taken along the line VB-VB in FIG. 5A, FIG. 5C is a schematic cross-sectional view taken along the line VC-VC in FIG. 5A, and FIG. 5D is a schematic cross-sectional view taken along the line VD-VD in FIG. 5A.

The semiconductor substrate 100 is provided with a p-type semiconductor region 511 serving as a p-type well and an n-type semiconductor region 512 serving as an n-type well. For example, the n-type semiconductor region 512 is an n-type epitaxial layer, whereas the p-type semiconductor region 511 is a p-type impurity diffusion region formed through ion implantation with a p-type impurity into the n-type epitaxial layer. A plurality of portions constituting a single semiconductor region, that is, each of the semiconductor regions 511 and 512, have the same conductivity type and are continuous to one another. Here, the plurality of portions are portions whose positions in at least any of X, Y, and Z directions are different. The plurality of portions constituting each of the semiconductor regions 511 and 512 may have different impurity concentrations. For example, the p-type semiconductor region 511 may have an impurity concentration that inclines in the depth direction (Z direction) of the semiconductor substrate 100. In the photoelectric conversion cell 111, the photoelectric conversion portion 301 and the photoelectric conversion portion 302 are arranged along a front surface 1000 of the semiconductor substrate 100. The direction in which the photoelectric conversion portions 301 and 302 are arranged is the X direction, the direction parallel to the front surface 1000 and vertical to the X direction is the Y direction, and the direction vertical to the front surface 1000 is the Z direction.

As a structure different from that illustrated in FIGS. 5A to 5D, the photoelectric conversion portions 301 and 302 may be arranged in the Z direction. That is, one of the photoelectric conversion portions 301 and 302 may be located at a position in the semiconductor substrate 100 deeper than the other. For example, the cathode (n-type semiconductor region) of the photoelectric conversion portion 301 and the anode (p-type semiconductor region) of the photoelectric conversion portion 302 are located in the Z direction from the front surface 1000. Also, the anode (p-type semiconductor region) of the photoelectric conversion portion 301 and the cathode (n-type semiconductor region) of the photoelectric conversion portion 302 are located therebetween so as to achieve p-n junction isolation. With a p-type semiconductor region serving as a charge movement path that is connected to the anode of the photoelectric conversion portion 302 being extended toward the front surface 1000, signal charge of the photoelectric conversion portion 302 located at a deep position can be collected through the charge movement path. In this case, however, the amount of light subjected to photoelectric conversion by the photoelectric conversion portion at a shallower position is different from the amount of light subjected to photoelectric conversion by the photoelectric conversion portion at a deeper position, and accordingly a great difference occurs in the amount of signal charge to be generated. This is because the light is absorbed in the semiconductor substrate 100 and is attenuated. Thus, for the purpose of decreasing the difference in the amount of received light between the photoelectric conversion portions 301 and 302, the photoelectric conversion portions 301 and 302 may be arranged along the front surface 1000 of the semiconductor substrate 100.

In FIGS. 5A to 5D, bold lines represent local wiring lines provided in the photoelectric conversion cell 111. Circles represent the positions of contact portions that are used to establish a connection between the semiconductor substrate 100 and the local wiring lines or global wiring lines (not illustrated) such as the row wiring lines 120 and the column wiring lines 130 described above with reference to FIG. 1B. At a typical contact portion, a contact plug and the semiconductor substrate 100 are connected to each other. Here, a local wiring line is a wiring line for electrically connecting elements in the photoelectric conversion cell 111 to each other. On the other hand, a global wiring line is a wiring line for connecting the photoelectric conversion cells 111 to each other or connecting the photoelectric conversion cells 111 to a circuit outside the cell array 110. The row wiring lines 120 and the column wiring lines 130 described above with reference to FIG. 1B are typical global wiring lines. A wiring line is a member composed of a conductor for establishing an electrical connection. At a contact portion for establishing a connection with a semiconductor region, a region of the semiconductor region connected to a conductor such as a contact plug is an impurity region of high concentration compared to the other region, and thereby favorable electrical connection may be ensured.

As illustrated in FIG. 5B, in the Y direction, an n-type semiconductor region 507, a transfer gate electrode 503, an n-type semiconductor region 501, a transfer gate electrode 504, and an n-type semiconductor region 508 are arranged in this order along the line VB-VB.

As illustrated in FIG. 5C, in the Y direction, a p-type semiconductor region 510, a transfer gate electrode 505, a p-type semiconductor region 502, a transfer gate electrode 506, and a p-type semiconductor region 509 are arranged in this order along the line VC-VC.

As illustrated in FIG. 5A, in the X direction, a gate electrode 513 of the reset transistor 313, a gate electrode 515 of the amplification transistor, and a gate electrode 516 of the selection transistor 316 are arranged in this order. The gate electrode 515 of the amplification transistor constituting the signal generation portion 315 serves as an input node of the signal generation portion 315 and is connected to the detection node 220 directly or via an electric low-pass filter 433.

As illustrated in FIG. 5A, in the X direction, a gate electrode 514 of the reset transistor 314, a gate electrode 525 of the amplification transistor, and a gate electrode 536 of the selection transistor 326 are arranged in this order. The gate electrode 525 of the amplification transistor constituting the signal generation portion 325 serves as an input node of the signal generation portion 325 and is connected to the detection node 230 directly or via the electric low-pass filter 433.

As illustrated in FIGS. 5A and 5B, an n-type semiconductor region 523, which corresponds to the source/drain regions of the reset transistor 313, is surrounded by a p-type semiconductor region 517 as a p-side well. Also, an n-type semiconductor region 524, which corresponds to the source/drain regions of the reset transistor 314, is surrounded by the p-type semiconductor region 517 as a p-side well. The same applies to the source/drain regions of the amplification transistor and the selection transistor. With use of the semiconductor regions 517 and 518, the source/drain regions of the transistors are isolated from the semiconductor region 511 or 512 through p-n junction (p-n junction isolation). Instead of the semiconductor regions 517 and 518, insulators having a LOCOS structure or STI structure may be used for isolation.

The n-type semiconductor region 507 is part of the capacitor portion 307 and constitutes the collection node 207. In other words, the n-type semiconductor region 507 is a first floating diffusion. The semiconductor region 511 forms a p-n junction in conjunction with the semiconductor region 507, and the semiconductor region 511 constitutes the reference node 217 of the capacitor portion 307.

The p-type semiconductor region 510 is part of the capacitor portion 310 and constitutes the collection node 210. In other words, the p-type semiconductor region 510 is a second floating diffusion. The semiconductor region 512 forms a p-n junction in conjunction with the semiconductor region 510, and the semiconductor region 512 constitutes the reference node 200 of the capacitor portion 310.

The n-type semiconductor region 501 is part of the photoelectric conversion portion 301 and constitutes the cathode 201 of the photodiode. The semiconductor region 501 forms a p-n junction in conjunction with the semiconductor region 511, and the semiconductor region 511 constitutes the anode 211 of the photodiode. The impurity concentration of the n-type semiconductor region 501 may be low enough to be depleted at a built-in potential. Accordingly, in the electron-hole pairs generated by the photoelectric conversion portion 301, the electrons generated as signal charge are less likely to be accumulated in the photoelectric conversion portion 301. As a result, the transfer efficiency of electrons from the photoelectric conversion portion 301 to the semiconductor region 507 increases. Also, electrons generated from light can be completely transferred to the semiconductor region 507, and noise caused by low transfer efficiency can be reduced. The holes not used as signal charge in the photoelectric conversion portion 301 are discharged through the p-type semiconductor region 511. A front surface region, which is a p-type semiconductor region, is provided between the n-type semiconductor region 501 and the front surface 1000 of the semiconductor substrate 100, and the n-type semiconductor region 501 is located apart from the front surface 1000. Accordingly, the photoelectric conversion portion 301 serves as a buried photodiode. In FIGS. 5A to 5D, the p-type semiconductor region serving as a front surface region is integrated with the p-type semiconductor region 511.

The p-type semiconductor region 502 is part of the photoelectric conversion portion 302 and constitutes the anode 202 of the photodiode. The semiconductor region 502 forms a p-n junction in conjunction with the semiconductor region 512, and the semiconductor region 512 constitutes the cathode 212 of the photodiode. The impurity concentration of the p-type semiconductor region 502 may be low enough to be depleted at a built-in potential. Accordingly, in the electron-hole pairs generated by the photoelectric conversion portion 302, the holes generated as signal charge are less likely to be accumulated in the photoelectric conversion portion 302. As a result, the transfer efficiency of holes from the photoelectric conversion portion 302 to the semiconductor region 510 increases. Also, holes generated from light can be completely transferred to the semiconductor region 510, and noise caused by low transfer efficiency can be reduced. The electrons not used as signal charge in the photoelectric conversion portion 302 are discharged through the p-type semiconductor region 511. A front surface region, which is an n-type semiconductor region, is provided between the p-type semiconductor region 502 and the front surface 1000 of the semiconductor substrate 100, and the p-type semiconductor region 502 is located apart from the front surface 1000. Accordingly, the photoelectric conversion portion 302 serves as a buried photodiode. In FIGS. 5A to 5D, the n-type semiconductor region serving as a front surface region is integrated with the n-type semiconductor region 512.

The n-type semiconductor region 508 forms a p-n junction in conjunction with the semiconductor region 511. The semiconductor region 508 is part of the capacitor portion 308 and constitutes the collection node 208. The p-type semiconductor region 509 forms a p-n junction in conjunction with the semiconductor region 512. The semiconductor region 509 is part of the capacitor portion 309 and constitutes the collection node 209. The n-type semiconductor region 501 and the p-type semiconductor region 502 are arranged in the X direction along the front surface 1000. The n-type semiconductor region 501 and the p-type semiconductor region 502 are isolated from each other, but may be in contact with each other. In this example, the p-type semiconductor region 511 and the n-type semiconductor region 512 form a p-n junction between the n-type semiconductor region 501 and the p-type semiconductor region 502. Accordingly, the semiconductor region 501 and the semiconductor region 502 are electrically isolated from each other (p-n junction isolation).

The reference potential VF1 is supplied to the semiconductor region 511 from a contact plug 611 that constitutes the reference potential supply portion 411. Also, the reference potential VF2 is supplied to the semiconductor region 512 from a contact plug 612 that constitutes the reference potential supply portion 412. The reference potential VF1 is lower than the reference potential VF2, and thereby a reverse bias voltage is applied between the semiconductor regions 511 and 512. Thus, a depletion layer generated between the semiconductor regions 511 and 512 causes the semiconductor regions 511 and 512 to be electrically isolated from each other. Accordingly, the electrons generated by the n-type semiconductor region 501 and the holes generated by the p-type semiconductor region 502 can be electrically isolated from each other. Thus, charge can be collected by a corresponding collection node at appropriate timing and signal charges for ranging can be selectively recombined. Also, the photoelectric conversion portions 301 and 302 are isolated from each other by p-n junction isolation and thereby the interval between the photoelectric conversion portions 301 and 302 can be decreased (for example, less than 1 μm). Accordingly, the difference in the amount of received light between the photoelectric conversion portions 301 and 302 can be decreased. Furthermore, the p-n junction isolation is able to suppress the occurrence of dark current compared to insulator isolation.

In the cell array 110, the photoelectric conversion cells 111 each having the structure illustrated in FIG. 5A are arranged in a matrix. The n-type semiconductor region 512 is provided among the plurality of photoelectric conversion cells 111, serving as a continuous common well. On the other hand, the p-type semiconductor region 511 is provided among the plurality of photoelectric conversion cells 111, serving as a discontinuous isolated well. That is, the p-type semiconductor region 511 of a certain photoelectric conversion cell 111 may be electrically isolated from the p-type semiconductor region 511 of at least one of the adjoining photoelectric conversion cells 111 by isolation such as p-n junction isolation. Contrary to the above-described example, the n-type semiconductor region 512 may serve as an isolated well and the p-type semiconductor region 511 may serve as a common well. In this way, with use of one of the n-type semiconductor region 512 and the p-type semiconductor region 511 as a common well, the configuration of the photoelectric conversion cell 111 can be simplified.

In plan view, the transfer gate electrode 503 that includes at least a portion located between the n-type semiconductor region 501 and the n-type semiconductor region 507 constitutes the transfer portion 303. In this example, the transfer gate electrode 503 is located above part of the semiconductor region 501 and part of the semiconductor region 507. In plan view, the transfer gate electrode 504 that includes at least a portion located between the n-type semiconductor region 501 and the n-type semiconductor region 508 constitutes the transfer portion 304. In this example, the transfer gate electrode 504 is located above part of the semiconductor region 501 and part of the semiconductor region 508.

In plan view, the transfer gate electrode 505 that includes at least a portion located between the p-type semiconductor region 502 and the p-type semiconductor region 510 constitutes the transfer portion 305. In this example, the transfer gate electrode 505 is located above part of the semiconductor region 502 and part of the semiconductor region 510. In plan view, the transfer gate electrode 506 that includes at least a portion located between the p-type semiconductor region 502 and the p-type semiconductor region 509 constitutes the transfer portion 306. In this example, the transfer gate electrode 506 is located above part of the semiconductor region 502 and part of the semiconductor region 509.

An insulating film 500 is provided between the semiconductor substrate 100 and the transfer gate electrodes 503, 504, 505, and 506. The insulating film 500 functions as a gate insulating film.

A local wiring line 618 is connected in common to the transfer gate electrodes 503 and 505 via contact plugs 603 and 605 so that the same transfer signal TX1 is supplied to the transfer gate electrodes 503 and 505. Here, the transfer gate electrodes 503 and 505 are provided as separate gate electrodes. A gate electrode performs charge/discharge every time it is driven and thus a current corresponding to MOS capacitance flows every time switching is performed. In the case of performing high-speed driving, the MOS capacitance decreases as the size of the gate electrode of the transistor decreases, and accordingly a small current flows and power is saved. Thus, with the transfer gate electrodes 503 and 505 being provided separately, the size of the gate electrodes can be decreased as much as possible.

Alternatively, an integrated gate electrode including a portion serving as the transfer portion 303 and a portion serving as the transfer portion 306 may be provided. With this configuration, the number of wiring lines can be decreased and the wiring capacitance and resistance can be decreased, and accordingly the accuracy of complementary control of the transfer portions 303 and 306 can be enhanced. Furthermore, a decreased number of wiring lines enables a higher aperture ratio and higher sensitivity. The same applies to the transfer gate electrodes 504 and 506, that is, an integrated gate electrode including a portion serving as the transfer portion 304 and a portion serving as the transfer portion 305 may be provided.

A reset transistor including the gate electrode 513 is connected to the semiconductor regions 507 and 510 via contact plugs 607 and 610, a local wiring line 620, and a contact plug 613. In this example, the local wiring line 620 constitutes the detection node 220. The gate electrode 513 is connected to the reset signal output portion 423 outside the cell array via a contact plug, a local wiring line, and a global wiring line. The contact plug 613 is connected to the semiconductor region 523, which corresponds to one of source/drain regions of the reset transistor. The other source/drain regions of the reset transistor are connected to the reset potential supply portion 413 outside the cell array via a global wiring line. Also, a reset transistor including the gate electrode 514 is connected to the semiconductor regions 508 and 509 via a local wiring line 630 and a contact plug. In this example, the local wiring line 630 constitutes the detection node 230. A contact plug 614 connected to the local wiring line 630 is connected to the semiconductor region 524, which corresponds to one of source/drain regions of the reset transistor. The contact plugs 613 and 614 deviating from the line VB-VB in FIG. 5A are illustrated in FIG. 5B as being located on the line VB-VB.

The amplification transistor including the gate electrode 515 is connected to the semiconductor regions 507 and 510 via the local wiring line 620 and a contact plug 615. The contact plug 615 is connected to the gate electrode 515 of the amplification transistor. The drain of the amplification transistor is connected to the power supply portion 432 via a contact plug and a global wiring line. The source of the amplification transistor is connected to the drain of the selection transistor 316 including the gate electrode 516. The source of the selection transistor 316 is connected to the output line 431, which is a global wiring line (the column wiring lines 130), via a contact plug. Also, an amplification transistor including the gate electrode 525 is connected to the semiconductor regions 508 and 509 via the local wiring line 630 and a contact plug. The source of the amplification transistor is connected to the drain of the selection transistor 326 including the gate electrode 536. The source of the selection transistor 326 is connected to the output line 441, which is a global wiring line (the column wiring lines 130), via a contact plug.

The contact plug 611 is connected to the semiconductor region 511. The contact plug 611 is connected to the reference potential supply portion 411 outside the cell array 110 via a global wiring line. The contact plug 612 is connected to the semiconductor region 512. The contact plug 612 is connected to the reference potential supply portion 412 outside the cell array 110 via a global wiring line. In this way, a reference potential is supplied to the semiconductor regions 511 and 512 via wiring lines, and thereby variations in the reference potential in the individual photoelectric conversion cells 111 in the cell array 110 can be decreased. Alternatively, a reference potential may be supplied without locating the contact plugs 611 and 612 in the photoelectric conversion cells 111. In this case, an impurity diffusion layer extending from the inside of the cell array 110 to the outside thereof may be provided on the semiconductor substrate 100, and a reference potential may be supplied to the impurity diffusion layer outside the cell array 110 via a wiring line and a contact plug. However, as described above, when the p-type semiconductor region 511 is an isolated well, it is difficult to extend the p-type semiconductor region 511 to the outside of the cell array 110. Thus, regarding at least an isolated well, a reference potential may be supplied thereto via a conductor provided on the semiconductor substrate 100, such as a global wiring line, a local wiring line, and a contact plug. The same applies to the case where the n-type semiconductor region 512 is an isolated well.

The semiconductor regions 507 and 510 are connected to each other via a conductor. In this example, the conductor that connects the semiconductor regions 507 and 510 includes the local wiring line 620 and the contact plugs 607 and 610. The conductor that connects the semiconductor regions 507 and 510 is made of a material with a higher conductivity than the semiconductor substrate 100, such as a metallic material, a metal compound material, or polysilicon. A metallic material and a metal compound material are used for wiring lines and contact plugs, and polysilicon is used for gate electrodes. The metal compound material may be a semiconductor-metal compound material such as silicide. These materials are used alone or in combination to connect the semiconductor regions 507 and 510. In this way, the semiconductor regions 507 and 510 are connected to each other via a conductor and thus the semiconductor regions 507 and 510 can be connected to each other without using a p-n junction. Typically, the semiconductor regions 507 and 510 can be connected to each other via an ohmic contact. With the semiconductor regions 507 and 510 being connected to each other via a conductor, a configuration in which the semiconductor regions 507 and 510 do not form a p-n junction is obtained. Thus, in the case of recombining electrons and holes, the time for alleviating a potential difference between the semiconductor regions 507 and 510 can be shortened. As a result, the output of the detection node 220 can be stabilized and highly accurate ranging can be realized.

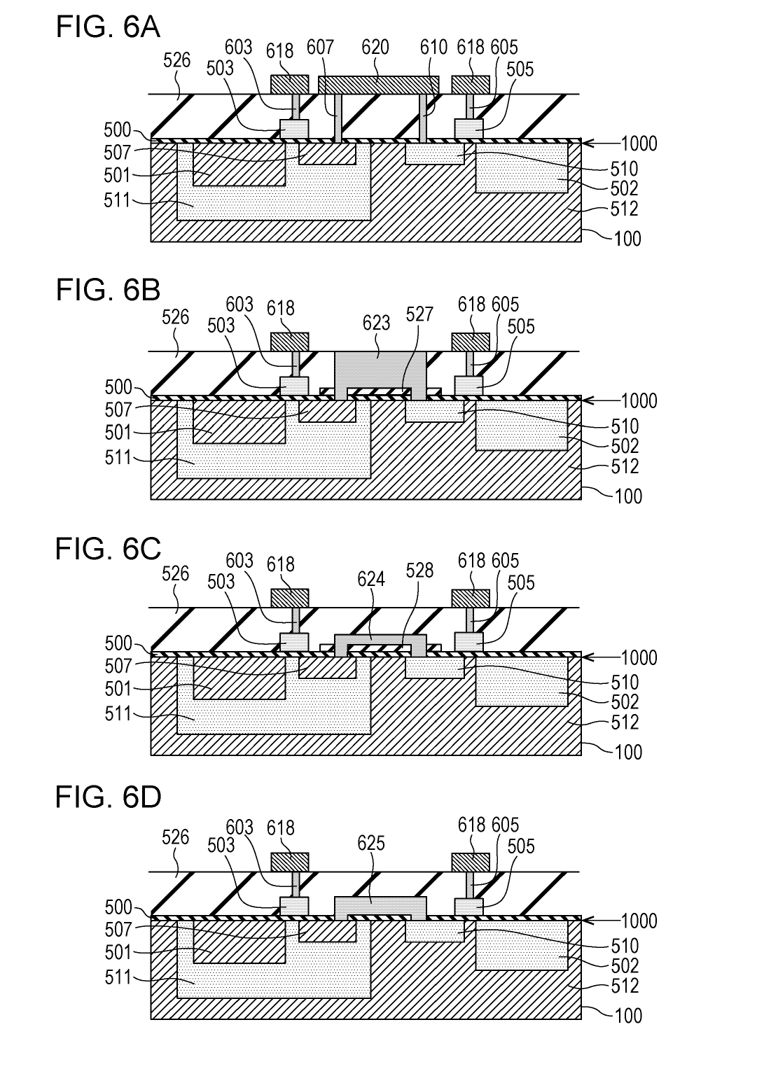

FIGS. 6A to 6D illustrate example structures for obtaining the electrical connection between the semiconductor regions 507 and 510. FIGS. 6A to 6D correspond to a cross-section including the transfer gate electrodes 503 and 505 and the semiconductor regions 507 and 510 illustrated in FIG. 5A. FIG. 6A illustrates a structure for obtaining the electrical connection between the semiconductor regions 507 and 510 in FIGS. 5A to 5D. FIGS. 6B to 6D illustrate forms different from the form in FIG. 6A for obtaining the electrical connection between the semiconductor regions 507 and 510. In FIGS. 6A to 6D, the transfer gate electrodes 503 and 505 are electrically connected to each other via the local wiring line 618. The local wiring line 618 is in contact with the contact plug 603 on the transfer gate electrode 503 and the contact plug 605 on the transfer gate electrode 505. The contact plugs 603 and 605 extend through an interlayer insulating film 526, and the local wiring line 618 is located on the interlayer insulating film 526. The local wiring line 618 may be, for example, an aluminum wiring line including a conductive portion mainly containing aluminum and a barrier metal portion including a titanium layer and/or titanium nitride layer. Alternatively, the local wiring line 618 may be a copper wiring line including a conductive portion mainly containing copper and a barrier metal portion including a tantalum layer and/or tantalum nitride layer. The copper wiring line has a single damascene structure or dual damascene structure. The other local wiring lines are also aluminum wiring lines or copper wiring lines.

In the form illustrated in FIG. 6A, the semiconductor regions 507 and 510 are connected to each other via the contact plugs 607 and 610 and the local wiring line 620 that connects the contact plugs 607 and 610. The contact plug 607 is connected to the semiconductor region 507 via the interlayer insulating film 526, and the contact plug 610 is connected to the semiconductor region 510 via the interlayer insulating film 526. The contact plugs 607 and 610 each include a conductive portion mainly containing tungsten and a barrier metal portion that is located between the conductive portion and the interlayer insulating film 526 and that includes a titanium layer and/or titanium nitride layer. The local wiring line 620 is an aluminum wiring line including a conductive portion mainly containing aluminum and a barrier metal portion that is located between the conductive portion and the interlayer insulating film 526 and that includes a titanium layer and/or titanium nitride layer. Alternatively, the local wiring line 620 is a copper wiring line including a conductive portion mainly containing copper and a barrier metal portion that is located between the conductive portion and the interlayer insulating film 526 and that includes a tantalum layer and/or tantalum nitride layer.

In the form illustrated in FIG. 6B, the semiconductor regions 507 and 510 are connected to each other via a contact plug 623, which is a conductor that is in contact with both the semiconductor regions 507 and 510. The contact plug 623 includes a conductive portion mainly containing tungsten and a barrier metal portion that is located between the conductive portion and the interlayer insulating film 526 and that includes a titanium layer and/or a titanium nitride layer. An insulating film 527, which is separated from the insulating film 500 and the interlayer insulating film 526, is provided between the contact plug 623 and the semiconductor substrate 100. The insulating film 527 insulates the contact plug 623 and the p-type semiconductor region 511 from each other and insulates the contact plug 623 and the n-type semiconductor region 512 from each other. Accordingly, an electrical connection between the p-type semiconductor region 511 and the n-type semiconductor region 512 can be suppressed.

In the form illustrated in FIG. 6C, the semiconductor regions 507 and 510 are connected to each other via a local wiring line 624, which is a conductor that is in contact with both the semiconductor regions 507 and 510. The local wiring line 624 can be formed by patterning a tungsten film or silicide film. The local wiring line 624 is located between the interlayer insulating film 526 and the semiconductor substrate 100. The local wiring line 624 may be formed after the transfer gate electrodes 503 and 505 have been formed, and then the interlayer insulating film 526 and the contact plugs 603 and 605 may be formed. An insulating film 528, which is separated from the insulating film 500 and the interlayer insulating film 526, is provided between the local wiring line 624 and the semiconductor substrate 100. The insulating film 528 insulates the local wiring line 624 and the p-type semiconductor region 511 from each other and insulates the local wiring line 624 and the n-type semiconductor region 512 from each other. Accordingly, an electrical connection between the p-type semiconductor region 511 and the n-type semiconductor region 512 can be suppressed.

In the form illustrated in FIG. 6D, the semiconductor regions 507 and 510 are connected to each other via a local wiring line 625, which is a conductor that is in contact with both the semiconductor regions 507 and 510. The local wiring line 625 can be formed by patterning a polysilicon film and can be formed at the same time as the transfer gate electrodes 503 and 505. The local wiring line 625 is located between the interlayer insulating film 526 and the semiconductor substrate 100. The insulating film 500 is located between the local wiring line 625 and the semiconductor substrate 100 so as to achieve insulation between the local wiring line 625 and the p-type semiconductor region 511 and insulation between the local wiring line 625 and the n-type semiconductor region 512.

The above-described local wiring lines and global wiring lines can be constituted by connecting a plurality of wiring layers stacked in the direction vertical to the front surface 1000 of the semiconductor substrate 100 to one another by using via plugs.

A description has been given above of the case where the sensitivities of the photoelectric conversion portions 301 and 302 are different from each other. Also in a case where the transfer characteristics of the photoelectric conversion portions 301 and 302 are different from each other or in a case where the transfer characteristics of the transfer portions 303, 304, 305, and 306 are different from each other, the signal levels at the detection nodes 220 and 230 may shift in the same direction. The difference in transfer characteristics may occur due to a manufacturing error, and also may inevitably occur in a short transfer period due to a difference in movement speed between electrons and holes. Thus, as a result of obtaining the above-described difference signal, not only a sensitivity difference but also an error resulted from a difference in transfer characteristics can be reduced or removed. A coefficient r proportional to a sensitivity difference (sensitivity ratio) may be regarded as a coefficient based on not only a difference in sensitivity but also a difference in transfer characteristics. An error component based on sensitivity or transfer characteristics is not constant regardless of an amount of charge, but depends on an amount of charge. Thus, reducing or removing an error component by using a potential at the detection nodes 220 and 230 that changes in accordance with an amount of charge is an appropriate method for reducing error that takes into account the dependency of an error component on an amount of charge.

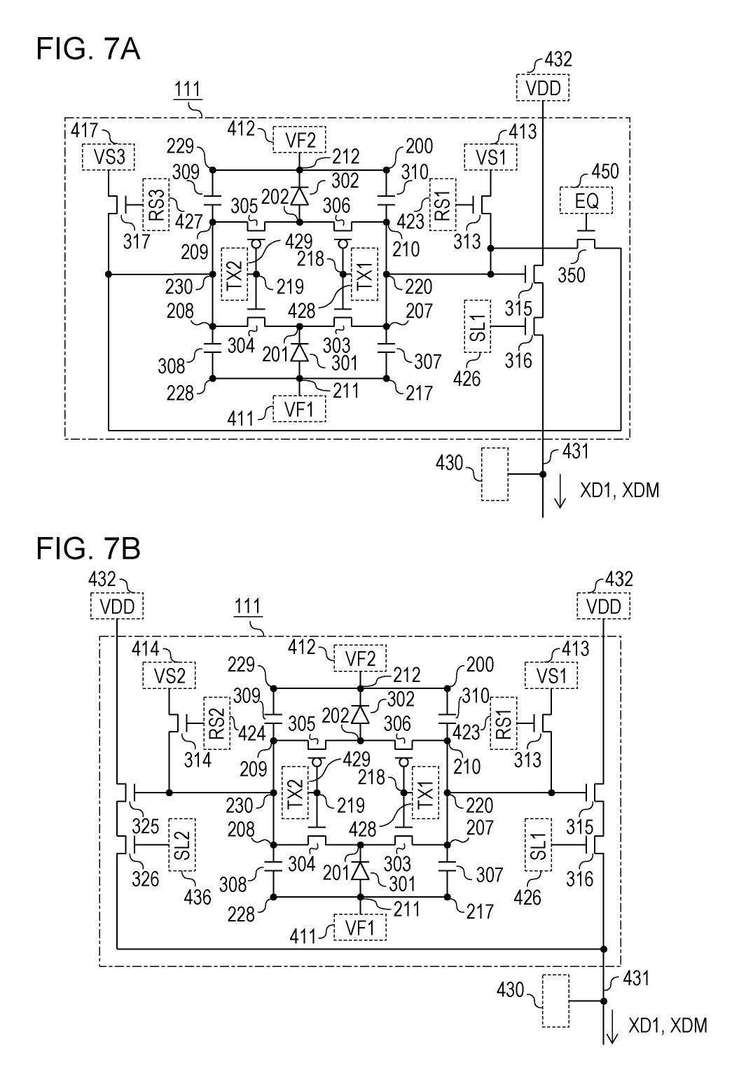

Next, modification examples of the photoelectric conversion cell 111 will be described with reference to FIGS. 7A and 7B. Also in the modification examples, a signal correlated with a difference between the detection potentials VD1 and VD2 (VD1−VD2) can be obtained.

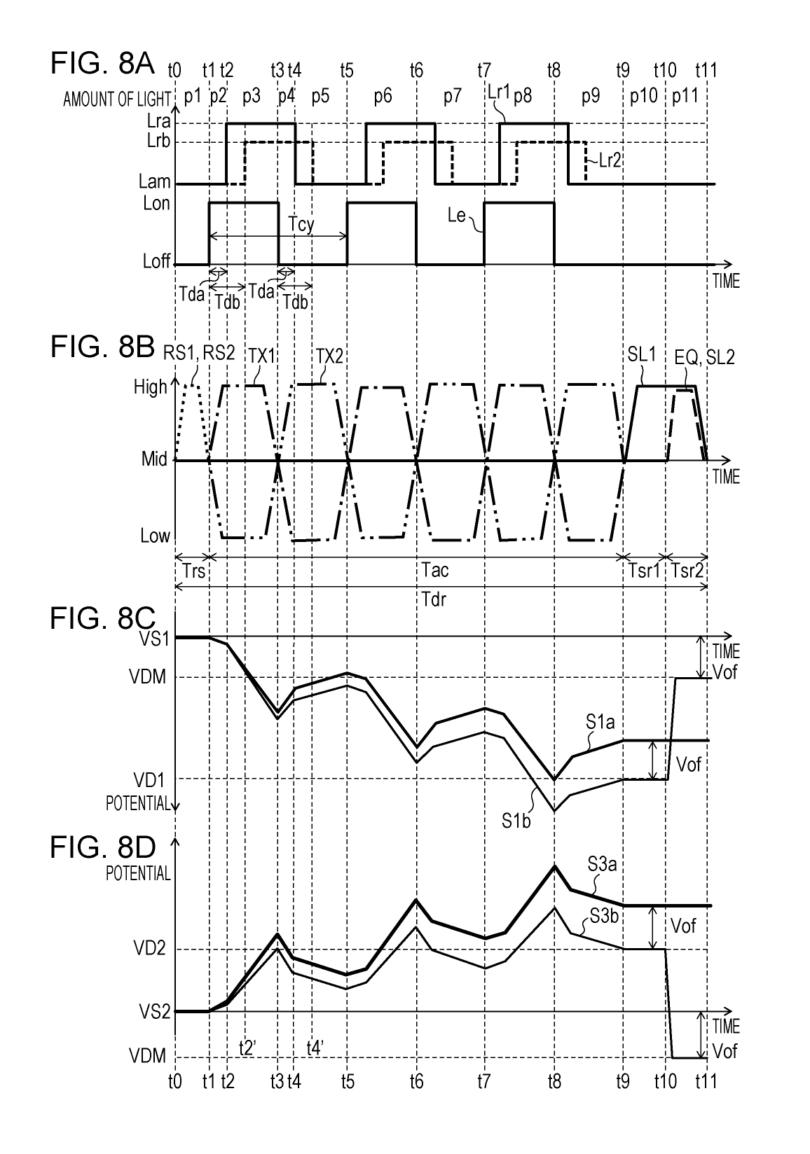

A first modification example illustrated in FIG. 7A has a configuration in which the detection nodes 220 and 230 are electrically connected to each other to obtain a composite potential of the detection potentials VD1 and VD2 in the photoelectric conversion cell 111. FIGS. 8A to 8D illustrate an example of the operation of the circuit illustrated in FIG. 7A.

A reset signal RS3 output from a reset signal output portion 427 causes a reset transistor 317 to be in an ON state. Accordingly, a reset potential VS3 is supplied from a reset potential supply portion 417 to the detection node 230. The reset transistor 317 may be omitted. In this case, the detection node 230 may be supplied with the reset potential VS3 through the reset transistor 313, and through a switch transistor 350 if necessary.

In one embodiment, the potential difference between the reset potential VS1 and the reset potential VS3 is less than 0.10 V and the potential difference between the reset potential VS1 and the reset potential VS3 is 0 V (VS1=VS3). However, a slight potential difference of less than 0.10 V due to inevitable resistance or manufacturing error is allowed. In one embodiment, the reset potential VS1 and the reset potential VS3 are potentials between the reference potential VF1 and the reference potential VF2. For example, the reset potential VS1 may be higher than the reference potential VF1 (VF1<VS1). Also, the reset potential VS3 may be lower than the reference potential VF2 (VS3<VF2). The reset potential VS1 is, for example, −1 to +1 V. In one embodiment, the reset potential VS1 is −0.5 to +0.5 V. The reset potential VS3 is, for example, −1 to +1 V, and in one embodiment, is −0.5 to +0.5 V.

With the reset potential VS1 being supplied to the capacitor portion 307, the electrons held by the capacitor portion 307 are discharged to the reset potential supply portion 413. With the reset potential VS2 being supplied to the capacitor portion 310, the holes held by the capacitor portion 310 are discharged to the reset potential supply portion 417.

In the example illustrated in FIG. 7A, the detection node 220 is connected to the detection node 230 via the switch transistor 350. In a state where charge is collected to the collection nodes 210 and 207, the signal generation portion 315 outputs the detection signal XD1 representing the signal level LD1 based on the detection potential VD1 at the detection node 220 to the output line 431. The detection signal XD1 is held in a memory. At this time, a switch signal output portion 450 is in an OFF state.

Subsequently, a switch signal EQ output from the switch signal output portion 450 causes the switch transistor 350 to be in an ON state. Accordingly, the detection nodes 220 and 230 are connected to each other. As a result, a composite potential VDM, which is an intermediate potential between the potential at the detection node 220 and the potential at the detection node 230, appears at the detection nodes 220 and 230. When it is assumed that the capacitance of the detection node 220 is represented by C1 and the capacitance of the detection node 230 is represented by C2, the composite capacitance of the detection nodes 220 and 230 connected to each other is C1+C2. The voltage that appears at the connected detection node 220 is expressed by VDM=(C1×VD1+C2×VD2)/(C1+C2). If the composite capacitances of the detection nodes 220 and 230 are equal to each other (C1=C2), a composite potential of the detection potentials VD1 and VD2 ((VD1+VD2)/2) is obtained by connecting the detection nodes 220 and 230 to each other. That is, the composite potential VDM is half the sum of the detection potentials VD1 and VD2. Even if the capacitances of the detection nodes 220 and 230 are different from each other, the potential VDM between the detection potentials VD1 and VD2 can be obtained. The signal generation portion 315 outputs a composite signal XDM representing a signal level LDM based on the composite potential VDM between the detection potential VD1 at the detection node 220 and the detection potential VD2 at the detection node 230 to the output line 431.

As illustrated in FIGS. 8A to 8D, there is the read period Tsr2 for reading an error signal just after the read period Tsr1. In the read periods Tsr1 and Tsr2, the selection transistor 316 is in an ON state, and in the read period Tsr2, the switch transistor 350 is in an ON state. Accordingly, in the read period Tsr1, a signal of the detection node 220 at which the potential corresponding to the potential at the collection node 207 is read. In the read period Tsr2, the composite potential of the detection nodes 220 and 230 is read.

As illustrated in FIGS. 8C and 8D, there is a potential difference Vof between the composite potential VDM and each of the reset potentials VS1 and VS2 in the period p11. The potential difference Vof is equal to a difference Vof between the detection potential of the potential change S1a in a case where there is no sensitivity difference and the detection potential VD1 of the potential change S1b in the period p10 in a case where there is a sensitivity difference. Thus, it is understood that the potential difference Vof represents a component of a sensitivity difference. The same applies to the potential changes S3a and S3b. If the difference between the reset potentials VS1 and VS2 increases, the deviation of the composite potential VDM from a pure sensitivity difference component increases. In one embodiment, the difference between the reset potentials VS1 and VS2 is as small as possible so that the composite potential VDM accurately reflects a sensitivity difference.

The composite potential VDM between the detection potentials VD1 and VD2 includes more signals resulted from a sensitivity difference than the detection potential VD1 or VD2, and thus the composite signal XDM is available as a correction signal for correcting a sensitivity difference. For example, the difference between the detection signal XD1 based on the detection potential VD1 and the composite signal XDM based on the composite potential VDM corresponds to the difference between the detection potential VD1 and the composite potential VDM. The difference between the detection potential VD1 and the composite potential VDM is expressed by VD1−VDM=VD1−(C1×VD1+C2×VD2)/(C1+C2)=(C1×VD1+C2×VD1−C1×VD1−C2×VD2)/(C1+C2)=(VD1−VD2)×C2/(C1+C2). When C1=C2, (VD1−VD2)/2. In this way, the difference between the detection potential VD1 and the composite potential VDM is proportional to VD1−VD2. As described above, VD1−VD2 is a signal related to the highly accurate signal light 82 with a reduced sensitivity difference between photoelectric conversion portions and a reduced influence of the ambient light 83, and is able to correct an error resulted from a sensitivity difference.

For example, the detection signal XD1 and a correction signal XDM are input to a differential circuit in the following stage. The differential circuit generates information including a signal representing the difference between the signal level LD1 of the detection signal XD1 and the signal level LDM of the correction signal XDM. The information is information correlated with the difference between the detection potentials VD1 and VD2 (VD1−VD2) and has a reduced error resulted from a sensitivity difference. In this way, as a result of extracting a difference signal (VD1−VDM), distance information with a reduced error can be obtained. The differential circuit in the following stage can be provided in the signal processing part 160 illustrated in FIG. 1B or the processing unit 40 illustrated in FIG. 1A.

A second modification example illustrated in FIG. 7B has a configuration in which the signal generation portion 315 and the signal generation portion 325 are electrically connected to each other and thereby the composite signal XDM corresponding to the composite potential of the detection potentials VD1 and VD2 is obtained in the photoelectric conversion cell 111.

In the second modification example, the signal generation portion 315 is connected to the output line 431 via the selection transistor 316 serving as a switch, and the signal generation portion 325 is connected to the output line 431 via the selection transistor 326 serving as a switch. In the read period Tsr1 illustrated in FIG. 8B, the selection transistor 316 is in an ON state, and the selection transistor 326 is in an OFF state. Accordingly, in the read period Tsr1, the detection signal XD1 representing the signal level LD1 corresponding to the detection potential VD1 at the detection node 220 is read. Subsequently, in the read period Tsr2, both the selection transistors 316 and 326 are in an ON state. At this time, if the selection transistor 316 is in an OFF state, the detection signal XD2 representing the signal level LD2 corresponding to the detection potential VD2 at the detection node 230 is read. However, since the selection transistor 316 is in an OFF state, the signal that is output is the composite signal XDM representing the signal level LDM between the signal levels LD1 and LD2. The composite signal XDM has a signal level corresponding to (VD1−VD2)×C2/(C1+C2) described above in the first modification example. Thus, as a result of obtaining the difference between the signal level LD1 of the detection signal XD1 and the signal level LDM of the composite signal XDM, information correlated with (VD1−VD2) can be obtained. A circuit for obtaining the difference may be a differential circuit or subtraction circuit provided in the photoelectric conversion device 11. Alternatively, a differential circuit or subtraction circuit for obtaining the difference may be provided in the processing unit 40. Accordingly, in the read period Tsr2, a signal representing the signal level LD1 and a signal corresponding to the composite potential of the detection nodes 220 and 230 are read. In this way, a signal representing an error of a ranging signal can be easily obtained.

The ranging apparatus 1 described above as an optical apparatus including the photoelectric conversion device 11 generates information correlated with the difference between the detection potentials VD1 and VD2. The information is information in which an error resulted from a difference between the characteristics of the photoelectric conversion portion 301 and the transfer portions 303 and 304 that handle electrons and the characteristics of the photoelectric conversion portion 302 and the transfer portions 305 and 306 that handle holes is reduced or removed. Accordingly, the accuracy of information based on electrons generated by a photoelectric conversion portion and holes generated by a photoelectric conversion portion can be enhanced. Thus, it is possible to obtain a signal with a reduced influence of a difference in characteristics between the photoelectric conversion portions 301 and 302, compared to the case of generating a signal by using only one of the detection potential VD1 at the detection node 220 and the detection potential VD2 at the detection node 230.

Application examples of the information processing system SYS will be described with reference to FIG. 1A.

A first application example of the information processing system SYS is an example of applying it to a camera equipped with an image capturing apparatus. The information processing apparatus 2 operates the ranging apparatus 1 upon receipt of a signal indicating an instruction to perform ranging from the control apparatus 3 including an input unit such as a focus control unit (for example, a focus button). Subsequently, the ranging apparatus 1 outputs a signal including distance information representing the distance to the target 9, which is a subject, to the information processing apparatus 2. The information processing apparatus 2 processes the signal and generates a drive signal for driving mechanical components such a lens, diaphragm, and shutter so as to satisfy conditions suitable for capturing an image of the target 9. The information processing apparatus 2 then outputs the drive signal to the driving apparatus 4 such as a motor that drives the lens, diaphragm, and shutter. The driving apparatus 4 drives these mechanical components in response to the drive signal. Upon receipt of a signal indicating an instruction to capture an image from the control apparatus 3, the information processing apparatus 2 instructs the image capturing apparatus 5 to capture an image, and accordingly the image capturing apparatus 5 captures an image of the target 9. The information processing apparatus 2 displays the image obtained from the image capturing apparatus 5 on the display apparatus 6. The information processing apparatus 2 is capable of displaying the obtained image on the display apparatus 6 together with distance information. The communication apparatus 7 communicates with a storage apparatus or a network and stores the image in the storage apparatus or a storage over the network.

A second application example of the information processing system SYS is an example of applying it to a video information processing system that provides a user with mixed reality. When the information processing apparatus 2 operates the ranging apparatus 1 and the image capturing apparatus 5, the image capturing apparatus 5 captures an image of the target 9 as a subject and outputs it as a real image. On the other hand, the ranging apparatus 1 outputs a signal including distance information representing the distance to the target 9 as a subject. The information processing apparatus 2 processes the signal and generates a composite image by combining a virtual image formed by using computer graphics or the like and the real image obtained through capturing by the image capturing apparatus 5 on the basis of the distance information. The information processing apparatus 2 displays the composite image on the display apparatus 6 such as a head mounted display.

A third application example of the information processing system SYS is an example of applying it to a transport apparatus that moves under power (for example, a car or train). Upon receipt of a signal indicating an instruction to move the transport apparatus or to get ready to move it from the control apparatus 3 that includes a device for generating a signal to start an engine (for example, a start button) and an input unit such as a handle and accelerator, the information processing apparatus 2 operates the ranging apparatus 1. The ranging apparatus 1 outputs a signal including distance information representing the distance to the target 9 as a subject. The information processing apparatus 2 processes the signal, and displays a warning on the display apparatus 6 if, for example, the distance to the target 9 becomes short. The information processing apparatus 2 is capable of displaying information representing the distance to the target 9 on the display apparatus 6. Also, the information processing apparatus 2 is capable of reducing or increasing the speed of the transport apparatus by driving the driving apparatus 4 such as a brake or engine on the basis of the distance information. Furthermore, the information processing apparatus 2 is capable of adjusting the relative distance to a transport apparatus that is running ahead by driving the driving apparatus 4 such as a brake or engine on the basis of the distance information.

A fourth application example of the information processing system SYS is an example of applying it to a game system. A user instructs a main body of a game machine to use a gesture mode by using the control apparatus 3 including an input unit such as a controller. In response to the instruction from the user, the information processing apparatus 2 operates the ranging apparatus 1. Accordingly, the ranging apparatus 1 detects a movement (gesture) of the user as distance information. On the basis of the obtained distance information, the information processing apparatus 2 creates video in which a virtual character in the game is operated in accordance with the movement of the user. The information processing apparatus 2 displays the video on the display apparatus 6 connected to the main body of the game machine (information processing apparatus 2).

The photoelectric conversion device is not limited to the above-described examples and is applicable to various information processing systems SYS. In the above embodiment, a description has been given of examples of a photoelectric conversion device optimized to perform driving for ranging, and a ranging apparatus and image capturing system including the device. The photoelectric conversion device may perform driving for something other than ranging. For example, edge detection for detecting a contour of an object such as a human face, focal point detection using phase difference detection, or ranging may be performed by using a signal corresponding to a difference in signal charge between a plurality of photoelectric conversion portions. Such operations may be performed because a difference in the amount of received light between a plurality of photoelectric conversion portions can be detected on the basis of the magnitude of a signal output from a signal generation portion in accordance with a difference in signal charge. In general, a complicated structure such as a differential circuit may be necessary to obtain a difference between electric signals by converting signal charge into electric signals by using a signal generation portion such as a source follower circuit. However, the photoelectric conversion device according to the embodiment is capable of easily obtaining a difference in signal charge between a plurality of photoelectric conversion portions by using recombination between electrons and holes. Furthermore, by converting the difference in signal charge into an electric signal by using a signal generation portion having a simple structure, for example, a source follower circuit, the photoelectric conversion device is capable of obtaining a signal corresponding to a difference in signal charge between the plurality of photoelectric conversion portions. With a switch transistor being provided between a collection node and a detection node, a signal corresponding to original signal charge, not a signal corresponding to the difference between the plurality of photoelectric conversion portions, can be read separately from the signal corresponding to the difference. Accordingly, an image capturing operation can be performed.

According to an embodiment, the accuracy of a signal based on electrons generated by a photoelectric conversion portion and holes generated by a photoelectric conversion portion can be enhanced.

While the present invention has been described with reference to example embodiments, it is to be understood that the invention is not limited to the disclosed example embodiments. The scope of the following claims is to be accorded the broadest interpretation so as to encompass all such modifications and equivalent structures and functions.

This application claims the benefit of Japanese Patent Application No. 2016-130905 filed Jun. 30, 2016, which is hereby incorporated by reference herein in its entirety.

What is claimed is:

1. An apparatus including a photoelectric conversion device,
the photoelectric conversion device comprising:
a first photoelectric conversion portion configured to generate electrons;
a second photoelectric conversion portion configured to generate holes;
a first detection node connected to a first collection node and a second collection node, the first collection node configured to collect the electrons generated by the first photoelectric conversion portion, the second collection node configured to collect the holes generated by the second photoelectric conversion portion; and
a second detection node connected to a third collection node and a fourth collection node, the third collection node configured to collect the electrons generated by the first photoelectric conversion portion, the fourth collection node configured to collect the holes generated by the second photoelectric conversion portion,
wherein the apparatus generates a signal correlated with a difference between
a first potential at the first detection node, the first potential based on electrons that are generated by the first photoelectric conversion portion and collected to the first collection node in a first period, and based on holes that are generated by the second photoelectric conversion portion and collected to the second collection node in a second period different from the first period, and
a second potential at the second detection node, the second potential based on holes that are generated by the second photoelectric conversion portion and collected to the fourth collection node in the first period, and based on electrons that are generated by the first photoelectric conversion portion and collected to the third collection node in the second period.

2. The apparatus according to claim 1, wherein the apparatus generates, by using a signal representing a first level that is based on the first potential and a signal representing a second level that is based on the second potential, a signal representing a difference between the first level and the second level and serving as the signal correlated with the difference.

3. The apparatus according to claim 2, wherein the photoelectric conversion device further comprises
a first signal generation portion configured to generate the signal representing the first level in accordance with the first potential; and
a second signal generation portion configured to generate the signal representing the second level in accordance with the second potential.

4. The apparatus according to claim 2, wherein the photoelectric conversion device further comprises
a circuit configured to receive the signal representing the first level and the signal representing the second level and to output the signal representing the difference between the first level and the second level.

5. The apparatus according to claim 1, wherein the apparatus generates, by using a signal representing a first level that is based on the first potential and a signal representing a third level that is based on a third potential between the first potential and the second potential, a signal representing a difference between the first level and the third level and serving as the signal correlated with the difference.

6. The apparatus according to claim 1, wherein the apparatus generates, by using a signal representing a first level that is based on the first potential and a signal representing a third level between the first level and a second level that is based on the second potential, a signal representing a difference between the first level and the third level and serving as the signal correlated with the difference.

7. The apparatus according to claim 5, wherein the photoelectric conversion device further comprises
a circuit configured to receive the signal representing the first level and the signal representing the third level and to output the signal representing the difference between the first level and the third level.

8. The apparatus according to claim 1, wherein a ratio between a length of the first period and a length of the second period is ⅔ or more and 3/2 or less.

9. The apparatus according to claim 1, wherein the photoelectric conversion device further comprises
a reset potential supply portion configured to supply a reset potential to the first detection node and the second detection node before the first period and the second period.

10. An apparatus including a photoelectric conversion device,
the photoelectric conversion device comprising:
a first photoelectric conversion portion configured to generate electrons;
a second photoelectric conversion portion configured to generate holes;
a first detection node connected to a first collection node and a second collection node, the first collection node configured to collect the electrons generated by the first photoelectric conversion portion, the second collection node configured to collect the holes generated by the second photoelectric conversion portion;
a second detection node connected to a third collection node and a fourth collection node, the third collection node configured to collect the electrons generated by the first photoelectric conversion portion, the fourth collection node configured to collect the holes generated by the second photoelectric conversion portion; and
a switch configured to connect the first detection node and the second detection node to each other.

11. An apparatus including a photoelectric conversion device,
the photoelectric conversion device comprising:
a first photoelectric conversion portion configured to generate electrons;
a second photoelectric conversion portion configured to generate holes;
a first detection node connected to a first collection node and a second collection node, the first collection node configured to collect the electrons generated by the first photoelectric conversion portion, the second collection node configured to collect the holes generated by the second photoelectric conversion portion;
a second detection node connected to a third collection node and a fourth collection node, the third collection node configured to collect the electrons generated by the first photoelectric conversion portion, the fourth collection node configured to collect the holes generated by the second photoelectric conversion portion;
a first signal generation portion connected to the first detection node; and
a second signal generation portion connected to the second detection node.

12. The apparatus according to claim 11, wherein the photoelectric conversion device further comprises
a switch configured to connect an output of the first signal generation portion to an output of the second signal generation portion.

13. The apparatus according to claim 11, wherein the photoelectric conversion device further comprises
a first transfer portion configured to transfer the electrons generated by the first photoelectric conversion portion to the first collection node;
a second transfer portion configured to transfer the holes generated by the second photoelectric conversion portion to the second collection node;
a third transfer portion configured to transfer the electrons generated by the first photoelectric conversion portion to the third collection node; and
a fourth transfer portion configured to transfer the holes generated by the second photoelectric conversion portion to the fourth collection node.

14. The apparatus according to claim 13, wherein the first transfer portion and the second transfer portion are formed of a common electrode, and the third transfer portion and the fourth transfer portion are formed of a common electrode.

15. The apparatus according to claim 1, wherein the photoelectric conversion device further comprises
a first transfer portion configured to transfer the electrons generated by the first photoelectric conversion portion to the first collection node;
a second transfer portion configured to transfer the holes generated by the second photoelectric conversion portion to the second collection node;
a third transfer portion configured to transfer the electrons generated by the first photoelectric conversion portion to the third collection node; and
a fourth transfer portion configured to transfer the holes generated by the second photoelectric conversion portion to the fourth collection node, and
wherein the first transfer portion and the fourth transfer portion are in an on state whereas the second transfer portion and the third transfer portion are in an off state in the first period, and the first transfer portion and the fourth transfer portion are in an off state whereas the second transfer portion and the third transfer portion are in an on state in the second period.

16. The apparatus according to claim 11, wherein
an n-type first semiconductor region constituting the first collection node and a p-type second semiconductor region constituting the second collection node are connected to each other via a first conductor, and
an n-type third semiconductor region constituting the third collection node and a p-type fourth semiconductor region constituting the fourth collection node are connected to each other via a second conductor.

17. The apparatus according to claim 16, wherein
the first photoelectric conversion portion is a first photodiode,
the second photoelectric conversion portion is a second photodiode, and
a p-type fifth semiconductor region constituting an anode of the first photodiode and an n-type sixth semiconductor region constituting a cathode of the second photodiode form a p-n junction.

18. The apparatus according to claim 11, wherein
the photoelectric conversion device comprises a cell array including cells arranged in a matrix, each of the cells including the first photoelectric conversion portion, the second photoelectric conversion portion, the first detection node, and the second detection node, and
the apparatus generates a signal by using both a first potential at the first detection node and a second potential at the second detection node, and obtains the signal with a smaller influence of a difference in characteristics between the first photoelectric conversion portion and the second photoelectric conversion portion than in a case of generating a signal by using only one of the first potential and the second potential.

19. The apparatus according to claim 1, further including:
a light emitting device configured to be repeatedly turned on and turned off.

20. The apparatus according to claim 1, further including:
an information processing apparatus configured to process information obtained from the photoelectric conversion device.

21. The apparatus according to claim 20, wherein light emitted by a light emitting device and reflected by a target is received by the photoelectric conversion device, and data corresponding to a distance from the photoelectric conversion device to the target is generated by using the information.

22. The apparatus according to claim 21, further including:
at least one of a display apparatus configured to display the information processed by the information processing apparatus and a driving apparatus configured to be driven based on the information processed by the information processing apparatus.

23. The apparatus according to claim 11, further including:
a light emitting device configured to be repeatedly turned on and turned off.

24. The apparatus according to claim 23, further including:
an information processing apparatus configured to process information obtained from the photoelectric conversion device,
wherein light emitted by the light emitting device and reflected by a target is received by the photoelectric conversion device, and data corresponding to a distance from the photoelectric conversion device to the target is generated by using the information.

25. An apparatus according to claim 11, further including:
an information processing apparatus configured to process information obtained from the photoelectric conversion device, and
a driving apparatus configured to be driven based on the information processed by the information processing apparatus.
